(19) United States
(12) Patent Application Publication
(10) Pub. No.: US 2026/0353650 A1
(43) Pub. Date: Nov. 5, 2026

(54) SEMICONDUCTOR MEMORY DEVICE INCLUDING PERIPHERAL GATE ELECTRODES

(71) Applicant: Samsung Electronics Co., Ltd., Suwon-si (KR)

(72) Inventor: Moonyoung Jeong, Suwon-si (KR)

(73) Assignee: Samsung Electronics Co., Ltd., Suwon-si (KR)

(21) Appl. No.: 19/662,994

(22) Filed: Apr. 29, 2026

(30) Foreign Application Priority Data
Apr. 30, 2025 (KR) 10-2025-0057157

(51) Int. Cl. H10B 12/00; H10B 80/00; H10W 90/00; H10W 90/26

(52) U.S. Cl. CPC H10B 12/50; H10B 12/315; H10B 80/00; H10W 90/26; H10W 90/792

(57) ABSTRACT

A semiconductor memory device includes a substrate including a cell array area and a peripheral circuit area, a cell active pattern extending in a first direction in the cell array area of the substrate, a wordline and a first cell shielding gate electrode spaced apart in the first direction on the cell active pattern; a plurality of first peripheral gate electrodes spaced apart in a second direction on the peripheral circuit area of the substrate; a plurality of first and second peripheral active patterns, both extending in the first direction and adjacent to one another in the second direction, the plurality of first and second peripheral active patterns and the plurality of second peripheral active patterns respectively between adjacent ones of the plurality of first peripheral gate electrodes in the second direction; and a plurality of first peripheral shielding gate electrodes.

### CROSS-REFERENCE TO RELATED APPLICATIONS

This present application claims priority to and the benefit under 35 U.S.C. § 119(a)-(d) of Korean Patent Application No. 10-2025-0057157, filed on Apr. 30, 2025, in the Korean Intellectual Property Office, the entire disclosure of which is incorporated herein by reference.

### FIELD

The present disclosure relates to a semiconductor memory device, and more particularly, to a semiconductor memory device including a vertical channel transistor (VCT).

### BACKGROUND

To satisfy consumer demands for excellent performance and low cost, increasing the integration density of semiconductor memory devices is required. In semiconductor memory devices, the integration density is a key factor in determining product price, and is therefore particularly important.

In the case of two-dimensional (2D) or planar semiconductor memory devices, the integration density is mainly determined by the area occupied by each unit memory cell, and is therefore greatly affected by the level of fine pattern formation technology. However, achieving finer patterns requires extremely expensive equipment, and thus although the integration density of 2D semiconductor memory devices is increasing, it still remains limited. Accordingly, semiconductor memory devices including vertical channel transistors (VCTs), in which channels extend in a vertical direction, have been proposed.

### SUMMARY

According to aspects of the present disclosure, there is provided a semiconductor memory device including a substrate including a cell array area and a peripheral circuit area; a cell active pattern extending in a first direction in the cell array area of the substrate; a wordline and a first cell shielding gate electrode spaced apart in the first direction on the cell active pattern; a plurality of first peripheral gate electrodes spaced apart in a second direction on the peripheral circuit area of the substrate; a plurality of first peripheral active patterns and a plurality of second peripheral active patterns, both extending in the first direction and adjacent to one another in the second direction, the plurality of first peripheral active patterns and the plurality of second peripheral active patterns respectively between adjacent ones of the plurality of first peripheral gate electrodes in the second direction; and a plurality of first peripheral shielding gate electrodes respectively spaced apart in the first direction from the plurality of first peripheral gate electrodes.

According to embodiments of the present disclosure, there is provided a semiconductor memory device including a substrate including a cell array area and a peripheral circuit area; a plurality of first peripheral gate electrodes extending in a first direction and arranged in a second direction, on the peripheral circuit area of the substrate; a plurality of second peripheral gate electrode extending in the first direction respectively between the plurality of first peripheral gate electrodes; a plurality of peripheral active patterns extending in a third direction and including first dopant regions and second dopant regions, between each of the plurality of first peripheral gate electrodes and each of the plurality of the second peripheral gate electrodes; a plurality of first peripheral shielding gate electrodes spaced apart in the third direction from the plurality of first peripheral gate electrodes; a plurality of second peripheral shielding gate electrodes spaced apart in the third direction from the plurality of second peripheral gate electrodes; and a plurality of conductive patterns on the second dopant regions of the plurality of peripheral active patterns, wherein the plurality of first peripheral shielding gate electrodes and the plurality of second peripheral shielding gate electrodes overlap the second dopant regions of the plurality of peripheral active patterns in the second direction.

According to embodiments of the present disclosure, there is provided a semiconductor memory device including a substrate including a cell array area and a peripheral circuit area; and a cell structure and a peripheral circuit structure on the substrate, the cell structure and the peripheral circuit structure overlapping in a first direction and being electrically connected, wherein the cell structure includes a plurality of memory cells on the cell array area of the substrate and a plurality of first peripheral transistors on the peripheral circuit area of the substrate, the peripheral circuit structure includes a plurality of second peripheral transistors, the plurality of memory cells include a plurality of cell transistors and a plurality of cell capacitors, and the plurality of first peripheral transistors include a first peripheral active pattern extending in the first direction, and a first peripheral gate electrode and a first peripheral shielding gate electrode spaced apart in the first direction on the first peripheral active pattern.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing exemplary embodiments thereof in detail with reference to the attached drawings, in which:

FIG. 1 is a layout view of a semiconductor memory device according to some embodiments;

FIG. 2 is a layout view of a boundary portion between a cell array area and a peripheral circuit area in FIG. 1;

FIG. 3 is an enlarged layout view of portion R1 in FIG. 2;

FIG. 4 is an enlarged layout view of portion R2 in FIG. 2;

FIG. 5 is a cross-sectional view taken along line A-A in FIG. 2;

FIG. 6 is a cross-sectional view taken along lines B-B and C-C in FIG. 2;

FIG. 7 is an enlarged cross-sectional view of portion P1 in FIG. 5;

FIG. 8 is an enlarged cross-sectional view of portion P2 in FIG. 5;

FIG. 9 is an enlarged cross-sectional view of portion P3 in FIG. 5;

FIGS. 10 and 11 are exemplary circuit diagrams of first peripheral transistor structures in FIGS. 8 and 9;

FIG. 12 is an enlarged cross-sectional view of portion P2 in FIG. 5;

FIG. 13 is an enlarged cross-sectional view of portion P3 in FIG. 5;

FIG. 14 is an exemplary circuit diagram of first peripheral transistor structures in FIGS. 12 and 13;

FIG. 15 is an enlarged cross-sectional view of portion P2 in FIG. 5;

FIG. 16 is an enlarged cross-sectional view of portion P3 in FIG. 5;

FIG. 17 is an exemplary circuit diagram of first peripheral transistor structures in FIGS. 15 and 16;

FIG. 18 is an enlarged cross-sectional view of portions P2 and P3 in FIG. 5;

FIG. 19 is an exemplary circuit diagram of a first peripheral transistor structure in FIG. 18;

FIG. 20 is an enlarged cross-sectional view of portions P2 and P3 in FIG. 5;

FIG. 21 is an exemplary circuit diagram of a first peripheral transistor structure in FIG. 20;

FIG. 22 is an enlarged cross-sectional view of portion P2 in FIG. 5;

FIG. 23 is an enlarged cross-sectional view of portion P3 in FIG. 5;

FIG. 24 is an enlarged cross-sectional view of portion P1 in FIG. 5;

FIG. 25 is a circuit diagram of a logic transistor of a semiconductor memory device according to some embodiments;

FIGS. 26, 28, 30, 31, and 33 are layout views of logic transistors of semiconductor memory devices according to some embodiments;

FIG. 27 is a cross-sectional view taken along line D-D in FIGS. 26, 30, or 33;

FIG. 29 is a cross-sectional view taken along line D-D in FIG. 28;

FIG. 32 is a cross-sectional view taken along line D-D in FIG. 31;

FIGS. 34 and 35 are cross-sectional views illustrating semiconductor memory devices according to some embodiments;

FIGS. 36 and 37 are enlarged cross-sectional views of portion P4 in FIG. 35; and

FIGS. 38 through 43 are cross-sectional views illustrating intermediate steps of a method for manufacturing a semiconductor memory device according to some embodiments.

### DETAILED DESCRIPTION

In this specification, terms such as first and second are used to describe various elements or components, but it is obvious that these elements or components are not limited by these terms. These terms are merely used to distinguish one element or component from another. Accordingly, a first element or component to be referred to below may also be a second element or component within the technical scope of the present disclosure.

The present disclosure provided a semiconductor memory device with improved integration density and electrical characteristics.

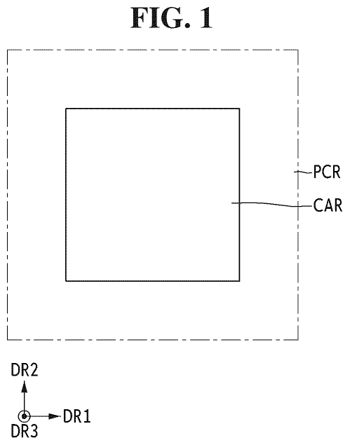

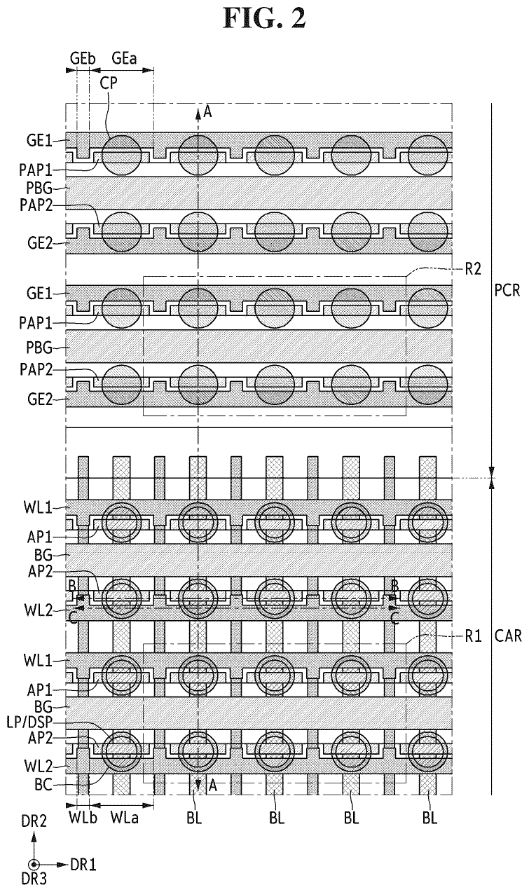

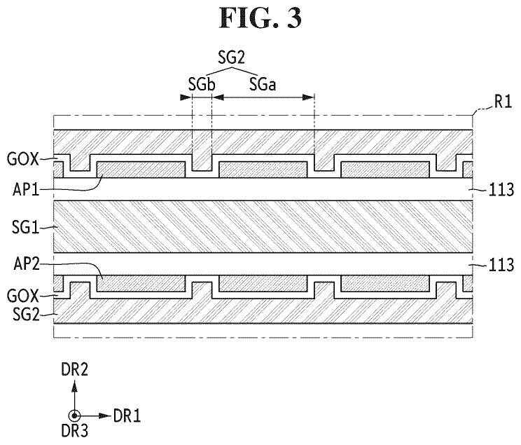

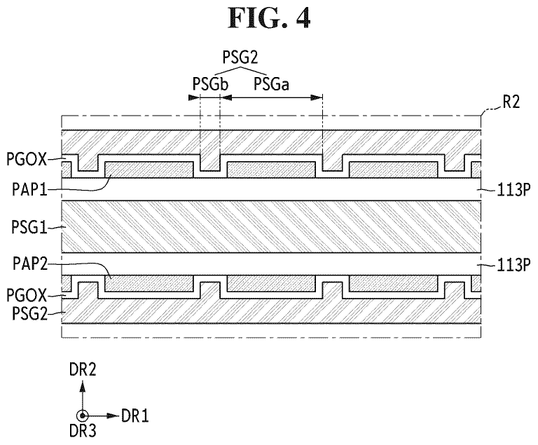

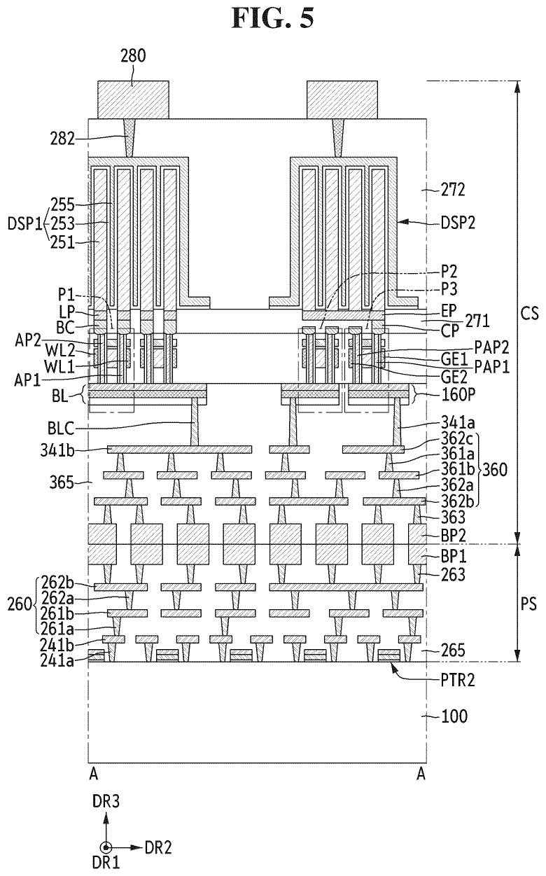

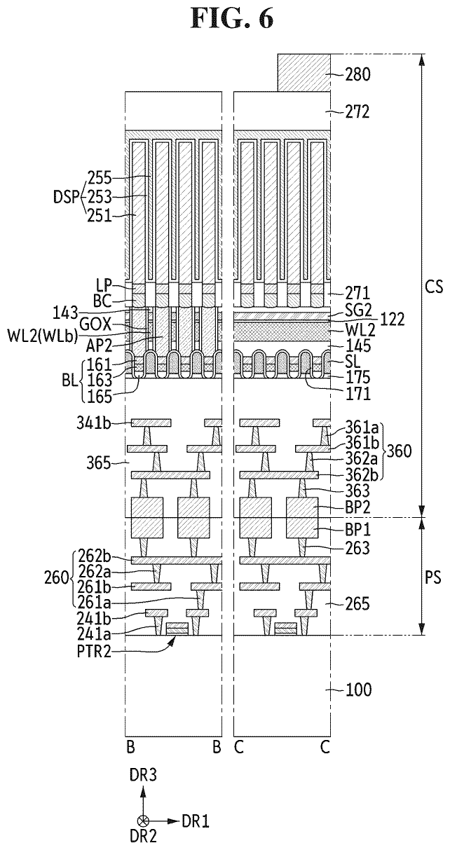

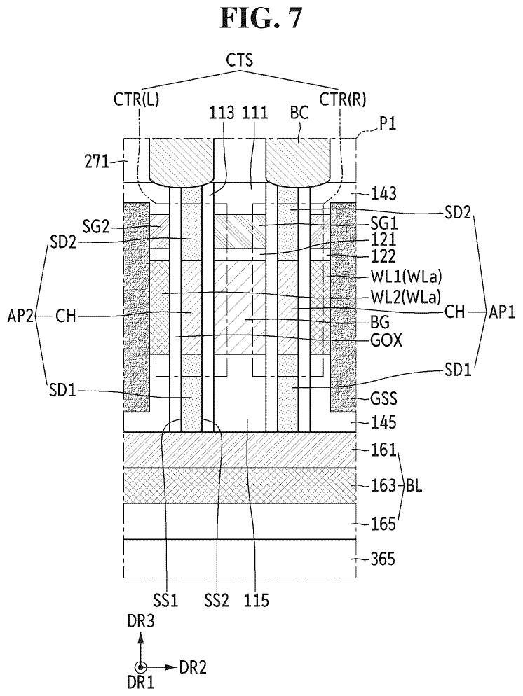

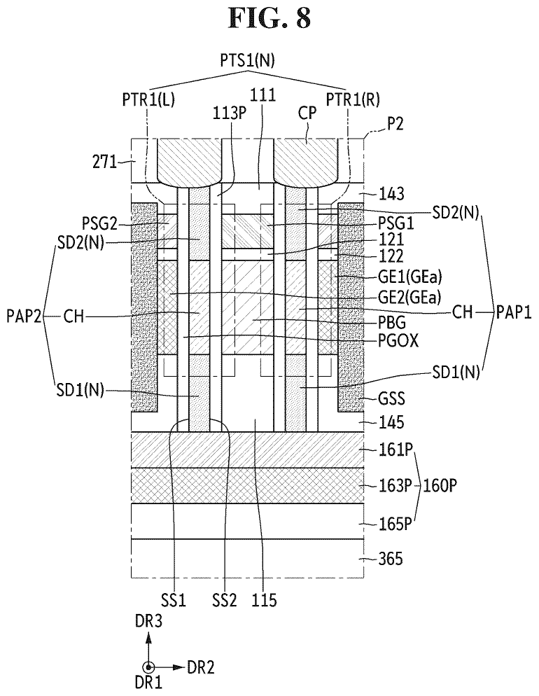

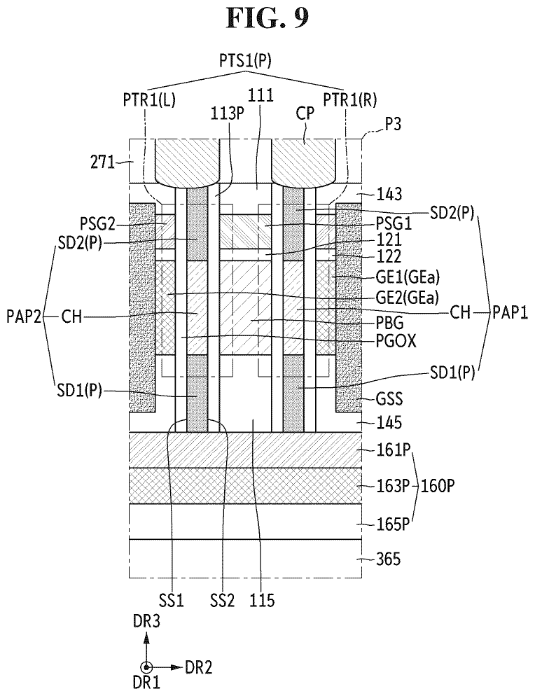

FIG. 1 is a layout view of a semiconductor memory device according to some embodiments. FIG. 2 is a layout view of a boundary portion between a cell array area and a peripheral circuit area in FIG. 1. FIG. 3 is an enlarged layout view of portion R1 in FIG. 2. FIG. 4 is an enlarged layout view of portion R2 in FIG. 2. FIG. 5 is a cross-sectional view taken along line A-A in FIG. 2. FIG. 6 is a cross-sectional view taken along lines B-B and C-C. FIG. 7 is an enlarged cross-sectional view of portion P1 in FIG. 5. FIG. 8 is an enlarged cross-sectional view of portion P2 in FIG. 5. FIG. 9 is an enlarged cross-sectional view of portion P3 in FIG. 5.

Referring to FIGS. 1 through 8, the semiconductor memory device according to some embodiments may include a substrate 100, a cell structure CS, and a peripheral circuit structure PS.

The substrate 100 may include a cell array area CAR and a peripheral circuit area PCR defined around the cell array area CAR. For example, the peripheral circuit area PCR may surround the cell array area CAR.

The substrate 100 may be a silicon substrate or may include other materials such as silicon germanium, indium antimonide, a lead telluride compound, indium arsenide, indium phosphide, gallium arsenide, or gallium antimonide, but is not limited thereto.

The cell structure CS and the peripheral circuit structure PS may be positioned on the substrate 100. The cell structure CS may overlap the peripheral circuit structure PS in a third direction DR3. In some embodiments, the cell structure CS may be stacked on the peripheral circuit structure PS. The peripheral circuit structure PS may be arranged between the substrate 100 and the cell structure CS.

The cell structure CS may include memory cells positioned in the cell array area CAR of the substrate 100 and first peripheral transistors PTR1 positioned in the peripheral circuit area PCR of the substrate 100. In some embodiments, each of the memory cells may have a structure in which one cell capacitor DSP1 is connected to one cell transistor CTR, and the cell transistor CTR may be a vertical channel transistor (VCT). Each of the memory cells may include a cell transistor CTR and a cell capacitor DSP1. A gate electrode of the cell transistor CTR may be connected to a wordline WL1 or WL2, a first source/drain electrode of the cell transistor CTR may be connected to a bitline BL, and a second source/drain electrode of the cell transistor CTR may be connected to the cell capacitor DSP1.

Alternatively, each of the memory cells may have a structure in which multiple cell capacitors DSP1 are connected to one cell transistor CTR. Alternatively, each of the memory cells may have a structure composed of cell transistors CTR without any cell capacitor DSP1.

Alternatively, each of the memory cells may have a vertically stacked dynamic random-access memory (VS-DRAM) structure in which first cell active patterns AP1 and second cell active patterns AP2 extend in a horizontal direction (e.g., a first direction DR1 or a second direction DR2). Alternatively, the cell transistors CTR of the memory cells may have a buried channel array transistor (BCAT) structure. In some embodiments, the first peripheral transistors PTR1 may be VCTs. The first peripheral transistors PTR1 may be connected to peripheral capacitors DSP2.

The peripheral circuit structure PS may include second peripheral transistors PTR2 positioned in the cell array area CAR and the peripheral circuit area PCR of the substrate 100. In some embodiments, the second peripheral transistors PTR2 may be transistors including planar field-effect transistors, fin field-effect transistors (FinFETs), nanowires, or nanosheets.

Core circuits such as a sub wordline driver and a sense amplifier may be positioned in the cell array area CAR of the peripheral circuit structure PS, and peripheral circuits such as a row decoder, a column decoder, and a control logic circuit may be positioned in the peripheral circuit area PCR of the peripheral circuit structure PS and the peripheral circuit area PCR of the cell structure CS. For example, the core circuits may be configured with the second peripheral transistors PTR2 in the cell array area CAR of the peripheral circuit structure PS, and the peripheral circuits may be configured with the second peripheral transistors PTR2 in the peripheral circuit area PCR of the peripheral circuit structure PS and the first peripheral transistors PTR1 in the peripheral circuit area PCR of the cell structure CS.

The cell structure CS may include a shielding structure (171, SL, and 175), bitlines BL, peripheral wirings 160P, first cell active patterns AP1, second cell active patterns AP2, first peripheral active patterns PAP1, second peripheral active patterns PAP2, cell back gate electrodes BG, peripheral back gate electrodes PBG, first wordlines WL1, second wordlines WL2, first peripheral gate electrodes GE1, second peripheral gate electrodes GE2, first cell shielding gate electrodes SG1, second cell shielding gate electrodes SG2, first peripheral shielding gate electrodes PSG1, second peripheral shielding gate electrodes PSG2, back gate capping patterns 115, first shielding isolation patterns 121, first shielding capping patterns 111, cell back gate insulating patterns 113, peripheral back gate insulating patterns 113P, gate capping patterns 145, gate separation patterns GSS, second shielding isolation patterns 122, cell gate insulating patterns GOX, peripheral gate insulating patterns PGOX, a first interlayer insulating film 271, contact patterns BC, conductive patterns CP, landing pads LP, electrode pads EP, cell capacitors DSP1, peripheral capacitors DSP2, a second interlayer insulating film 272, connection pads 280, connection pad plugs 282, a cell interlayer insulating film 365, bitline contacts BLC, peripheral contacts 341a, cell wiring lines 341b, and a cell connection structure 360.

The shielding structure (171, SL, and 175) may be positioned on the substrate 100.

The shielding structure (171, SL, and 175) may include shielding conductive patterns SL and shielding insulating films (171 and 175). For example, the shielding insulating films (171 and 175) may include shielding insulating liners 171 and shielding insulating capping films 175.

In the semiconductor memory device according to some embodiments, the shielding conductive patterns SL may have a line shape. The shielding conductive patterns SL may extend in the second direction DR2. The shielding conductive patterns SL may be adjacent in the first direction DR1. For example, the first and second directions DR1 and DR2 may be horizontal directions that intersect one another and are parallel to the substrate 100.

The shielding conductive patterns SL may extend from the cell array area CAR to the peripheral circuit area PCR. End portions of the shielding conductive patterns SL may be positioned in the peripheral circuit area PCR.

The shielding conductive patterns SL include a conductive material. For example, the shielding conductive patterns SL may include at least one of a conductive metal nitride, a conductive metal silicon nitride, a metal carbonitride, a conductive metal silicide, a conductive metal oxide, a two-dimensional (2D) material, or a metal. In the semiconductor memory device according to some embodiments, the 2D material may be a metallic and/or semiconductive material. The 2D material may include a 2D allotrope or a 2D compound. For example, the 2D material may include at least one of graphene, molybdenum disulfide (MoS₂), molybdenum diselenide (MoSe₂), tungsten diselenide (WSe₂), or tungsten disulfide (WS₂), but is not limited thereto. That is, the above-described 2D materials are listed by way of example, and the 2D material that may be included in the semiconductor memory device according to some embodiments is not particularly limited.

The shielding insulating capping films 175 may be positioned on the shielding conductive patterns SL. For example, the shielding insulating capping films 175 may contact the shielding conductive patterns SL. The shielding insulating capping films 175 may have a line shape extending in the second direction DR2 along the shielding conductive patterns SL.

Contrary to what is illustrated, the shielding insulating capping films 175 may have a plate shape. In other words, the shielding insulating capping films 175 may overlap the bitlines BL in the third direction DR3. For example, the third direction DR3 may be a vertical direction perpendicular to the substrate 100.

The shielding insulating liners 171 may be positioned on the shielding conductive patterns SL. The shielding insulating liners 171 may extend along the profiles of the shielding conductive patterns SL. The shielding insulating liners 171 may be disposed between the bitlines BL and peripheral bonding pads BP1. Contrary to what is illustrated, from a cross-sectional perspective, shielding insulating liners 171 formed along the profiles of adjacent shielding conductive patterns SL in the first direction DR1 may be connected to one another.

The shielding insulating liners 171 and the shielding insulating capping films 175 may each include an insulating material. When the shielding insulating liners 171 and the shielding insulating capping films 175 include the same material, the boundaries between the shielding insulating liners 171 and the shielding insulating capping films 175 may not be distinguishable.

By arranging the shielding structure (171, SL, and 175) between adjacent bitlines BL in the first direction DR1, coupling noise between the bitlines BL may be reduced.

The bitlines BL may be positioned on the substrate 100. The bitlines BL may extend in the second direction DR2. Adjacent bitlines BL may be spaced apart in the first direction DR1. Each of the bitlines BL may include long sidewalls extending in the second direction DR2 and short sidewalls extending in the first direction DR1.

The bitlines BL may be arranged adjacent to the shielding conductive patterns SL. The bitlines BL may be arranged adjacent to the shielding conductive patterns SL in the first direction DR1. In other words, the shielding conductive patterns SL may extend in the second direction DR2 along the long sidewalls of the bitlines BL.

Each of the bitlines BL may be arranged between adjacent shielding conductive patterns SL in the first direction DR1. The bitlines BL may be positioned on the shielding insulating liners 171. For example, the shielding insulating liners 171 may contact the bitlines BL.

The bitlines BL may extend from the cell array area CAR to the peripheral circuit area PCR. End portions of the bitlines BL may be positioned in the peripheral circuit area PCR.

Each of the bitlines BL may include a front surface on which first cell active patterns AP1 and second cell active patterns AP2 are positioned, and a rear surface opposite to the front surface in the third direction DR3. In some embodiments, the shielding conductive patterns SL may not be positioned on the rear surfaces of the bitlines BL. In embodiments, each of the shielding conductive patterns SL may include a plate portion having a planar shape and protrusions protruding from the plate portion in the third direction DR3, and the plate portions of the shielding conductive patterns SL may be positioned on the rear surfaces of the bitlines BL.

Each of the bitlines BL may include a semiconductor pattern 161, a metal pattern 163, and a bitline mask pattern 165 that are sequentially stacked. Alternatively, contrary to what is illustrated, the bitlines BL may include the semiconductor patterns 161 or the metal patterns 163. Yet alternatively, the bitlines BL may not include the bitline mask patterns 165.

The semiconductor patterns 161 may include a conductive semiconductor material. The conductive semiconductor material may be, for example, a semiconductor material doped with impurities. The semiconductor patterns 161 may include at least one of polysilicon, polysilicon germanium, poly-germanium, amorphous silicon, amorphous silicon germanium, or amorphous germanium. The metal patterns 163 may include a conductive material including a metal. The metal patterns 163 may include at least one of a conductive metal nitride, a conductive metal silicon nitride, a metal carbonitride, a conductive metal silicide, a conductive metal oxide, a 2D material, or a metal. The bitline mask patterns 165 may include an insulating material. The bitline mask patterns 165 may include silicon nitride or silicon oxynitride, but are not limited thereto.

The peripheral wirings 160P may be positioned on the substrate 100. The peripheral wirings 160P may be positioned in the peripheral circuit area PCR. The peripheral wirings 160P may be spaced apart from the bitlines BL in a horizontal direction (e.g., the first direction DR1 or the second direction DR2) parallel to the substrate 100. Each of the peripheral wirings 160P may include a front surface on which first peripheral active patterns PAP1 and second peripheral active patterns PAP2 are positioned, and a rear surface opposite to the front surface in the third direction DR3.

The peripheral wirings 160P may be formed at the same time as the bitlines BL. The peripheral wirings 160P may have the same stacked structure as the bitlines BL. For example, each of the peripheral wirings 160P may include a peripheral semiconductor pattern 161P, a peripheral metal pattern 163P, and a peripheral mask pattern 165P. That is, the peripheral semiconductor patterns 161P include the same material as the semiconductor patterns 161, the peripheral metal patterns 163P include the same material as the metal patterns 163, and the peripheral mask patterns 165P include the same material as the bitline mask patterns 165.

Alternatively, contrary to what is illustrated, the peripheral wirings 160P may include the peripheral semiconductor patterns 161P or the peripheral metal patterns 163P. Yet alternatively, the peripheral wirings 160P may not include the peripheral mask patterns 165P.

The first cell active patterns AP1 and the second cell active patterns AP2 may be positioned on the bitlines BL. The first cell active patterns AP1 and the second cell active patterns AP2 may be alternately arranged along the second direction DR2. The first peripheral active patterns PAP1 and the second peripheral active patterns PAP2 may be positioned on the peripheral wirings 160P. The first peripheral active patterns PAP1 and the second peripheral active patterns PAP2 may be alternately arranged along the second direction DR2. The first cell active patterns AP1, the second cell active patterns AP2, the first peripheral active patterns PAP1, and the second peripheral active patterns PAP2 may be spaced apart from the substrate 100 in the third direction DR3.

The first cell active patterns AP1 may be spaced apart from one another in the first direction DR1. The first cell active patterns AP1 may be spaced at regular intervals. The second cell active patterns AP2 may be spaced apart from one another in the first direction DR1. The second cell active patterns AP2 may be spaced at regular intervals. The first cell active patterns AP1 may be spaced from the second cell active patterns AP2 in the second direction DR2. The first cell active patterns AP1 and the second cell active patterns AP2 may be arranged two-dimensionally along the first and second directions DR1 and DR2, which intersect one another.

The first peripheral active patterns PAP1 may be spaced apart from one another in the first direction DR1. The first peripheral active patterns PAP1 may be spaced at regular intervals. The second peripheral active patterns PAP2 may be spaced apart from one another in the first direction DR1. The second peripheral active patterns PAP2 may be spaced at regular intervals. The first peripheral active patterns PAP1 may be spaced from the second peripheral active patterns PAP2 in the second direction DR2. The first peripheral active patterns PAP1 and the second peripheral active patterns PAP2 may be arranged two-dimensionally along the first and second directions DR1 and DR2, which intersect one another.

The first cell active patterns AP1, the second cell active patterns AP2, the first peripheral active patterns PAP1, and the second peripheral active patterns PAP2 may each have a length in the first direction DR1, a width in the second direction DR2, and a height in the third direction DR3. The first cell active patterns AP1, the second cell active patterns AP2, the first peripheral active patterns PAP1, and the second peripheral active patterns PAP2 may each have a substantially uniform width. In addition, the width of the first cell active patterns AP1 may be the same as the width of the second cell active patterns AP2, and the width of the first peripheral active patterns PAP1 may be the same as the width of the second peripheral active patterns PAP2.

The width of each of the first cell active patterns AP1, second cell active patterns AP2, first peripheral active patterns PAP1, and second peripheral active patterns PAP2 may range from several nanometers to several tens of nanometers. For example, the width of each of the first cell active patterns AP1, second cell active patterns AP2, first peripheral active patterns PAP1, and second peripheral active patterns PAP2 may range from 1 nm to 30 nm, and more preferably, from 1 nm to 10 nm, but is not limited thereto. The length of each of the first cell active patterns AP1 and second cell active patterns AP2 may be greater than the line width of the bitlines BL. That is, the length of each of the first cell active patterns AP1 and second cell active patterns AP2 may be greater than the width of the bitlines BL in the first direction DR1.

For example, the first cell active patterns AP1, the second cell active patterns AP2, the first peripheral active patterns PAP1, and the second peripheral active patterns PAP2 may each include a monocrystalline semiconductor material. In one example, the first cell active patterns AP1, the second cell active patterns AP2, the first peripheral active patterns PAP1, and the second peripheral active patterns PAP2 may each include monocrystalline silicon. In another example, the first cell active patterns AP1, the second cell active patterns AP2, the first peripheral active patterns PAP1, and the second peripheral active patterns PAP2 may each include at least one of polycrystalline semiconductor, oxide semiconductor, or a 2D material. Here, the polycrystalline semiconductor may be, for example, polysilicon, and the oxide semiconductor may be, for example, indium gallium zinc oxide (IGZO).

The first cell active patterns AP1, the second cell active patterns AP2, the first peripheral active patterns PAP1, and the second peripheral active patterns PAP2 may each include a first surface and a second surface that are opposite to one another in the third direction DR3. The first surfaces of the first cell active patterns AP1 and second cell active patterns AP2 may be connected to the bitlines BL. The first surfaces of the first cell active patterns AP1 and second cell active patterns AP2 may be connected to the semiconductor patterns 161 or the metal patterns 163 of the bitlines BL. The second surfaces of the first cell active patterns AP1 and second cell active patterns AP2 may be connected to the contact patterns BC. The first surfaces of the first peripheral active patterns PAP1 and second peripheral active patterns PAP2 may be connected to the peripheral semiconductor patterns 161P or the peripheral metal patterns 163P of the peripheral wirings 160P. The second surfaces of the first peripheral active patterns PAP1 and second peripheral active patterns PAP2 may be connected to the conductive patterns CP.

The first cell active patterns AP1, the second cell active patterns AP2, the first peripheral active patterns PAP1, and the second peripheral active patterns PAP2 may each include a first sidewall SS1 and a second sidewall SS2 that are opposite to one another in the second direction DR2. The first sidewalls SS1 of the first cell active patterns AP1 may face the second sidewalls SS2 of the second cell active patterns AP2, respectively, and the first sidewalls SS1 of the first peripheral active patterns PAP1 may face the second sidewalls SS2 of the second peripheral active patterns PAP2, respectively.

The first cell active patterns AP1, the second cell active patterns AP2, the first peripheral active patterns PAP1, and the second peripheral active patterns PAP2 may each include a first dopant region SD1, a second dopant region SD2, and a channel region CH between the first and second dopant regions SD1 and SD2. The first dopant regions SD1 and the second dopant regions SD2 are regions in the first cell active patterns AP1, the second cell active patterns AP2, the first peripheral active patterns PAP1, and the second peripheral active patterns PAP2 that are doped with dopants. The first dopant regions SD1 of the first cell active patterns AP1 and second cell active patterns AP2 may be connected to the bitlines BL. The second dopant regions SD2 of the first cell active patterns AP1 and second cell active patterns AP2 may be connected to the cell capacitors DSP1. The first dopant regions SD1 of the first peripheral active patterns PAP1 and second peripheral active patterns PAP2 may be connected to the peripheral wirings 160P, and the second dopant regions SD2 of the first peripheral active patterns PAP1 and second peripheral active patterns PAP2 may be connected to the peripheral capacitors DSP2.

During the operation of the semiconductor memory device according to some embodiments, the channel regions CH of the first cell active patterns AP1 and second cell active patterns AP2 may be controlled by the first wordlines WL1, the second wordlines WL2, and the cell back gate electrodes BG, and the channel regions CH of the first peripheral active patterns PAP1 and second peripheral active patterns PAP2 may be controlled by the first peripheral gate electrodes GE1, the second peripheral gate electrodes GE2, and the peripheral back gate electrodes PBG. When the first cell active patterns AP1, the second cell active patterns AP2, the first peripheral active patterns PAP1, and the second peripheral active patterns PAP2 include a monocrystalline semiconductor material, the leakage current characteristics of the semiconductor memory device according to some embodiments may be improved.

The cell back gate electrodes BG may be positioned on the bitlines BL and the shielding conductive patterns SL. The cell back gate electrodes BG may be spaced apart from one another in the second direction DR2. The cell back gate electrodes BG may be spaced at regular intervals. The cell back gate electrodes BG may extend across the bitlines BL in the first direction DR1.

Each of the cell back gate electrodes BG may be positioned between adjacent first and second cell active patterns AP1 and AP2 in the second direction DR2. Each of the cell back gate electrodes BG may be positioned between the first and second sidewalls SS1 and SS2 of the adjacent first and second cell active patterns AP1 and AP2. Each of the cell back gate electrodes BG may be positioned on the first and second sidewalls SS1 and SS2 of the adjacent first and second cell active patterns AP1 and AP2. The height of the cell back gate electrodes BG in the third direction DR3 may be less than the height of the first cell active patterns AP1 and second cell active patterns AP2.

The first cell active patterns AP1 may be positioned between the first wordlines WL1 and the cell back gate electrodes BG. The second cell active patterns AP2 may be positioned between the second wordlines WL2 and the cell back gate electrodes BG. A pair of first and second second wordlines WL1 and WL2 may be positioned between adjacent cell back gate electrodes BG in the second direction DR2.

The peripheral back gate electrodes PBG may be positioned on the peripheral wirings 160P. The peripheral back gate electrodes PBG may be spaced apart from one another in the second direction DR2. The peripheral back gate electrodes PBG may be spaced at regular intervals. The peripheral back gate electrodes PBG may extend in the first direction DR1. The peripheral back gate electrodes PBG may also be referred to as peripheral gate electrodes.

Each of the peripheral back gate electrodes PBG may be positioned between adjacent first and second peripheral active patterns PAP1 and PAP2 in the second direction DR2. Each of the peripheral back gate electrodes PBG may be positioned between the first and second sidewalls SS1 of the adjacent first and second peripheral active patterns PAP1 and PAP2. Each of the peripheral back gate electrodes PBG may be positioned on the first and second sidewalls SS1 of the adjacent first and second peripheral active patterns PAP1 and PAP2. The height of the peripheral back gate electrodes PBG in the third direction DR3 may be less than the height of the first peripheral active patterns PAP1 and second peripheral active patterns PAP2.

The first peripheral active patterns PAP1 may be positioned between the first peripheral gate electrodes GE1 and the peripheral back gate electrodes PBG. The second peripheral active patterns PAP2 may be positioned between the second peripheral gate electrodes GE2 and the peripheral back gate electrodes PBG. A pair of first and second peripheral gate electrodes GE1 and GE2 may be positioned between adjacent peripheral back gate electrodes PBG in the second direction DR2.

During the operation of the semiconductor memory device according to some embodiments, a voltage may be applied to the cell back gate electrodes BG to adjust the threshold voltage of the cell transistors CTR. In addition, during the operation of the semiconductor memory device according to some embodiments, a voltage may be applied to the peripheral back gate electrodes PBG to adjust the threshold voltage of the first peripheral transistors PTR1. By adjusting the threshold voltages of the cell transistors CTR and the first peripheral transistors PTR1, degradation in the leakage current characteristics of the semiconductor memory device according to some embodiments may be prevented.

The first wordlines WL1 and the second wordlines WL2 may be positioned on the bitlines BL and the shielding conductive patterns SL. The first wordlines WL1 and the second wordlines WL2 may extend in the first direction DR1. The first wordlines WL1 and the second wordlines WL2 may be alternately arranged in the second direction DR2.

The first wordlines WL1 may be positioned on the second sidewalls SS2 of the first cell active patterns AP1. The second wordlines WL2 may be positioned on the first sidewalls SS1 of the second cell active patterns AP2. Each of the first cell active patterns AP1 and second cell active patterns AP2 may be positioned between adjacent first and second wordlines WL1 and WL2 in the second direction DR2.

The first wordlines WL1 and the second wordlines WL2 may be spaced apart from the bitlines BL and the contact patterns BC in the third direction DR3. The first wordlines WL1 and the second wordlines WL2 may be positioned between the bitlines BL and the contact patterns BC.

The first peripheral gate electrodes GE1 and the second peripheral gate electrodes GE2 may be positioned on the peripheral wirings 160P. The first peripheral gate electrodes GE1 and the second peripheral gate electrodes GE2 may extend in the first direction DR1. The first peripheral gate electrodes GE1 and the second peripheral gate electrodes GE2 may be alternately arranged in the second direction DR2.

The first peripheral gate electrodes GE1 may be positioned on the second sidewalls SS2 of the first peripheral active patterns PAP1. The second peripheral gate electrodes GE2 may be positioned on the first sidewalls SS1 of the second peripheral active patterns PAP2. Each of the first peripheral active patterns PAP1 and second peripheral active patterns PAP2 may be positioned between adjacent first and second peripheral gate electrodes GE1 and GE2 in the second direction DR2.

The first peripheral gate electrodes GE1 and the second peripheral gate electrodes GE2 may be spaced apart from the peripheral wirings 160P and the conductive patterns CP in the third direction DR3. The first peripheral gate electrodes GE1 and the second peripheral gate electrodes GE2 may be positioned between the peripheral wirings 160P and the conductive patterns CP.

The first wordlines WL1 and the second wordlines WL2 may each have a width in the second direction DR2. The width of the first wordlines WL1 and second wordlines WL2 on the bitlines BL may differ from the width of the first wordlines WL1 and second wordlines WL2 on the shielding conductive patterns SL.

For example, each of the first wordlines WL1 and second wordlines WL2 may include first portions WLa and second portions WLb. The width of the first portions WLa in the second direction DR2 may be smaller than the width of the second portions WLb in the second direction DR2. In one example, the first portions WLa may be positioned on the bitlines BL, and the second portions WLb may be positioned on the shielding conductive patterns SL. Contrary to what is illustrated, the width of the first portions WLa in the second direction DR2 may be the same as the width of the second portions WLb in the second direction DR2.

Each of the first wordlines WL1 and second wordlines WL2 may include first portions WLa and second portions WLb alternately arranged in the first direction DR1. Each of the first cell active patterns AP1 may be positioned between adjacent second portions WLb, in the first direction DR1, of a corresponding first wordline WL1. Each of the second cell active patterns AP2 may be positioned between adjacent second portions WLb, in the first direction DR1, of a corresponding second wordline WL2.

The first peripheral gate electrodes GE1 and the second peripheral gate electrodes GE2 may have substantially the same shape as the first wordlines WL1 and the second wordlines WL2. For example, the first peripheral gate electrodes GE1 and the second peripheral gate electrodes GE2 may each include first portions GEa and second portions GEb. The width of the first portions GEa in the second direction DR2 may be smaller than the width of the second portions GEb in the second direction DR2. Contrary to what is illustrated, the width of the first portions GEa in the second direction DR2 may be the same as the width of the second portions GEb in the second direction DR2.

Each of the first peripheral gate electrodes GE1 and second peripheral gate electrodes GE2 may include first portions GEa and second portions GEb alternately arranged in the first direction DR1. Each of the first peripheral active patterns PAP1 may be positioned between adjacent second portions GEb, in the first direction DR1, of a corresponding first peripheral gate electrode GE1. Each of the second peripheral active patterns PAP2 may be positioned between adjacent second portions GEb, in the first direction DR1, of a corresponding second peripheral gate electrode GE2.

The following description takes the first wordlines WL1 as an example. In one example, the height of the first wordlines WL1, in the third direction DR3 may be the same as the height of the cell back gate electrodes BG in the third direction DR3. In another example, the height of the first wordlines WL1 in the third direction DR3 may be greater than the height of the cell back gate electrodes BG in the third direction DR3. In yet another example, the height of the first wordlines WL1 in the third direction DR3 may be less than the height of the cell back gate electrodes BG in the third direction DR3.

The first wordlines WL1, the second wordlines WL2 and the cell back gate electrodes BG may each include a bottom surface facing the bitlines BL and a top surface facing the contact patterns BC. In one example, the height of the bottom surfaces of the first wordlines WL1 may be the same as the height of the bottom surfaces of the cell back gate electrodes BG.

In another example, the height of the bottom surfaces of the first wordlines WL1 may be greater than the height of the bottom surfaces of the cell back gate electrodes BG. In yet another example, the height of the bottom surfaces of the first wordlines WL1 may be less than the height of the bottom surfaces of the cell back gate electrodes BG.

In addition, in one example, the height of the top surfaces of the first wordlines WL1 may be the same as the height of the top surfaces of the cell back gate electrodes BG. In another example, the height of the top surfaces of the first wordlines WL1 may be greater than the height of the top surfaces of the cell back gate electrodes BG. In yet another example, the height of the top surfaces of the first wordlines WL1 may be less than the height of the top surfaces of the cell back gate electrodes BG.

The following description takes the first peripheral gate electrodes GE1 as an example. In one example, the height of the first peripheral gate electrodes GE1 in the third direction DR3 may be the same as the height of the peripheral back gate electrodes PBG in the third direction DR3. In another example, the height of the first peripheral gate electrodes GE1 in the third direction DR3 may be greater than the height of the peripheral back gate electrodes PBG. In yet another example, the height of the first peripheral gate electrodes GE1 in the third direction DR3 may be less than the height of the peripheral back gate electrodes PBG.

The first peripheral gate electrodes GE1, the second peripheral gate electrodes GE2, and the peripheral back gate electrodes PBG may each include a bottom surface facing the peripheral wirings 160P and a top surface facing the conductive patterns CP. In one example, the height of the bottom surfaces of the first peripheral gate electrodes GE1 may be equal to the height of the bottom surfaces of the peripheral back gate electrodes PBG. In another example, the height of the bottom surfaces of the first peripheral gate electrodes GE1 may be greater than the height of the bottom surfaces of the peripheral back gate electrodes PBG. In yet another example, the height of the bottom surfaces of the first peripheral gate electrodes GE1 may be less than the height of the bottom surfaces of the peripheral back gate electrodes PBG.

In addition, in one example, the height of the top surfaces of the first peripheral gate electrodes GE1 may be the same as the height of the top surfaces of the peripheral back gate electrodes PBG. In another example, the height of the top surfaces of the first peripheral gate electrodes GE1 may be greater than the height of the top surfaces of the peripheral back gate electrodes PBG. In yet another example, the height of the top surfaces of the first peripheral gate electrodes GE1 may be less than the height of the top surfaces of the peripheral back gate electrodes PBG.

The bottom surfaces of the first wordlines WL1, second wordlines WL2, first peripheral gate electrodes GE1, and second peripheral gate electrodes GE2 may be planar.

Alternatively, contrary to what is illustrated, the bottom surfaces of the first wordlines WL1, second wordlines WL2, first peripheral gate electrodes GE1, and second peripheral gate electrodes GE2 may be concavely rounded. Yet alternatively, each of the first wordlines WL1, second wordlines WL2, first peripheral gate electrodes GE1, and second peripheral gate electrodes GE2 may be in the form of spacers. In other words, the bottom surfaces of the first wordlines WL1, second wordlines WL2, first peripheral gate electrodes GE1, and second peripheral gate electrodes GE2 may be convexly rounded.

The top surfaces of the first wordlines WL1, second wordlines WL2, first peripheral gate electrodes GE1, and second peripheral gate electrodes GE2 may be planar. Alternatively, contrary to what is illustrated, the top surfaces of the first wordlines WL1, second wordlines WL2, first peripheral gate electrodes GE1, and second peripheral gate electrodes GE2 may have a concave curved surface. The bottom surfaces and top surfaces of the cell back gate electrodes BG and peripheral back gate electrodes PBG are illustrated as being planar, but are not limited thereto.

The first cell shielding gate electrodes SG1 may be positioned on the cell back gate electrodes BG. The first cell shielding gate electrodes SG1 may be spaced apart from the cell back gate electrodes BG in the third direction DR3. The first cell shielding gate electrodes SG1 may overlap at least portions of the cell back gate electrodes BG in the third direction DR3.

The second cell shielding gate electrodes SG2 may be respectively positioned on the first wordlines WL1 and the second wordlines WL2. The second cell shielding gate electrodes SG2 may be spaced apart from the first wordlines WL1 and the second wordlines WL2 in the third direction DR3. The second cell shielding gate electrodes SG2 may overlap at least portions of the first wordlines WL1 and second wordlines WL2 in the third direction DR3.

The first cell shielding gate electrodes SG1 and the second cell shielding gate electrodes SG2 may be positioned between adjacent first and second cell active patterns AP1 and AP2 in the second direction DR2. The height of the first cell shielding gate electrodes SG1 and second cell shielding gate electrodes SG2 in the third direction DR3 may be less than the height of the first cell active patterns AP1 and second cell active patterns AP2. The first cell shielding gate electrodes SG1 and the second cell shielding gate electrodes SG2 may overlap portions of the first cell active patterns AP1 and the second cell active patterns AP2 in the second direction DR2. For example, the first cell shielding gate electrodes SG1 and the second cell shielding gate electrodes SG2 may overlap portions of the second dopant regions SD2 of the first cell active patterns AP1 and second cell active patterns AP2 in the second direction DR2.

The first cell shielding gate electrodes SG1 may be positioned between the first sidewalls SS1 of the first cell active patterns AP1 and the second sidewalls SS2 of the second cell active patterns AP2. The first cell shielding gate electrodes SG1 may be positioned on the first sidewalls SS1 of the first cell active pattern sAP1 and the second sidewalls SS2 of the second cell active patterns AP2. The second cell shielding gate electrodes SG2 may be positioned on the second sidewalls SS2 of the first cell active patterns AP1 and the first sidewalls SS1 of the second cell active patterns AP2.

For example, in a plan view, the first cell shielding gate electrodes SG1 may have substantially the same shape as the cell back gate electrodes BG, and the second cell shielding gate electrodes SG2 may have substantially the same shape as the first wordlines WL1 and the second wordlines WL2.

The first cell shielding gate electrodes SG1 may extend in the first direction DR1, similar to the cell back gate electrodes BG. The cell back gate electrodes BG and the first cell shielding gate electrodes SG1 are illustrated as entirely overlapping in the third direction DR3, but are not limited thereto. Alternatively, the cell back gate electrodes BG and the first cell shielding gate electrodes SG1 may have different shapes or different areas in a plan view, and may thus only partially overlap in the third direction DR3.

The second cell shielding gate electrodes SG2 may extend in the first direction DR1, similar to the first wordlines WL1 and the second wordlines WL2. Each of the second cell shielding gate electrodes SG2 may include first portions SGa and second portions SGb alternately arranged along the first direction DR1. The width of the first portions SGa in the second direction DR2 may be smaller than the width of the second portions SGb in the second direction DR2. Each of the first cell active patterns AP1 may be positioned between adjacent second portions SGb, in the first direction DR1, of a corresponding second cell shielding gate electrode SG2 on a corresponding first wordline WL1. Each of the second cell active patterns AP2 may be positioned between adjacent second portions SGb, in the first direction DR1, of a corresponding second cell shielding gate electrode SG2 on a corresponding second wordline WL2.

The first portions SGa and second portions SGb of the second cell shielding gate electrodes SG2 may overlap the first portions WLa and second portions WLb of the first wordlines WL1 or second wordlines WL2 in the third direction DR3. The first wordlines WL1, the second wordlines WL2, and the second cell shielding gate electrodes SG2 are illustrated as entirely overlapping in the third direction DR3, but are not limited thereto. Alternatively, the first wordlines WL1, the second wordlines WL2, and the second cell shielding gate electrodes SG2 may have different shapes or different areas in a plan view, and may thus only partially overlap in the third direction DR3.

The first peripheral shielding gate electrodes PSG1 may be positioned on the peripheral back gate electrodes PBG. The first peripheral shielding gate electrodes PSG1 may be spaced apart from the peripheral back gate electrodes PBG in the third direction DR3. The first peripheral shielding gate electrodes PSG1 may overlap the peripheral back gate electrodes PBG in the third direction DR3.

The second peripheral shielding gate electrodes PSG2 may be respectively positioned on the first peripheral gate electrodes GE1 and the second peripheral gate electrodes GE2. The second peripheral shielding gate electrodes PSG2 may be spaced apart from the first peripheral gate electrodes GE1 and the second peripheral gate electrodes GE2 in the third direction DR3. The second peripheral shielding gate electrodes PSG2 may overlap the first peripheral gate electrodes GE1 and the second peripheral gate electrodes GE2 in the third direction DR3.

Each of the first peripheral shielding gate electrodes PSG1 and second peripheral shielding gate electrodes PSG2 may be positioned between adjacent first and second peripheral active patterns PAP1 and PAP2 in the second direction DR2. The first peripheral shielding gate electrodes PSG1 may be positioned between the first sidewalls SS1 of the first peripheral active patterns PAP1 and the second sidewalls SS2 of the second peripheral active patterns PAP2. The first peripheral shielding gate electrodes PSG1 may be positioned on the first sidewalls SS1 of the first peripheral active patterns PAP1 and the second sidewalls SS2 of the second peripheral active patterns PAP2. The second peripheral shielding gate electrodes PSG2 may be positioned on the second sidewalls SS2 of the first peripheral active patterns PAP1 and the first sidewalls SS1 of the second peripheral active patterns PAP2.

The height of the first peripheral shielding gate electrodes PSG1 and second peripheral shielding gate electrodes PSG2 in the third direction DR3 may be less than the height of the first peripheral active patterns PAP1 and second peripheral active patterns PAP2. The first peripheral shielding gate electrodes PSG1 and the second peripheral shielding gate electrodes PSG2 may overlap portions of the first peripheral active patterns PAP1 and second peripheral active patterns PAP2 in the second direction DR2. For example, the first peripheral shielding gate electrodes PSG1 and the second peripheral shielding gate electrodes PSG2 may overlap portions of the second dopant regions SD2 of the first peripheral active patterns PAP1 and second peripheral active patterns PAP2 in the second direction DR2.

For example, in a plan view, the first peripheral shielding gate electrodes PSG1 may have substantially the same shape as the peripheral back gate electrodes PBG, and the second peripheral shielding gate electrodes PSG2 may have substantially the same shape as the first peripheral gate electrodes GE1 and the second peripheral gate electrodes GE2.

The first peripheral shielding gate electrodes PSG1 may extend in the first direction DR1, similar to the peripheral back gate electrodes PBG. The peripheral back gate electrodes PBG and the first peripheral shielding gate electrodes PSG1 are illustrated as entirely overlapping in the third direction DR3, but are not limited thereto. Alternatively, the peripheral back gate electrodes PBG and the first peripheral shielding gate electrodes PSG1 may have different shapes or different areas in a plan view, and may thus only partially overlap in the third direction DR3.

The second peripheral shielding gate electrodes PSG2 may extend in the first direction DR1, similar to the first peripheral gate electrodes GE1 and the second peripheral gate electrodes GE2. Each of the second peripheral shielding gate electrodes PSG2 may include first portions PSGa and second portions PSGb alternately arranged along the first direction DR1. The width of the first portions PSGa in the second direction DR2 may be smaller than the width of the second portions PSGb in the second direction DR2. Each of the first peripheral active patterns PAP1 may be positioned between adjacent second portions PSGb, in the first direction DR1, of a corresponding second peripheral shielding gate electrode PSG2 on a corresponding first peripheral gate electrode GE1. Each of the second peripheral active patterns PAP2 may be positioned between adjacent second portions PSGb, in the first direction DR1, of a corresponding second peripheral shielding gate electrode PSG2 on a corresponding second peripheral gate electrode GE2.

The first portions PSGa and second portions PSGb of the second peripheral shielding gate electrodes PSG2 may overlap the first portions GEa and second portions GEb of the first peripheral gate electrodes GE1 and second peripheral gate electrodes GE2 in the third direction DR3. The first peripheral gate electrodes GE1, the second peripheral gate electrodes GE2, and the second peripheral shielding gate electrode PSG2 are illustrated as entirely overlapping in the third direction DR3, but are not limited thereto. Alternatively, the first peripheral gate electrodes GE1, the second peripheral gate electrodes GE2, and the second peripheral shielding gate electrode PSG2 may have different shapes or different areas in a plan view, and may thus only partially overlap in the third direction DR3.

Each of the first wordlines WL1, second wordlines WL2, first peripheral gate electrodes GE1, second peripheral gate electrodes GE2, cell back gate electrodes BG, peripheral back gate electrodes PBG, first cell shielding gate electrodes SG1, second cell shielding gate electrodes SG2, first peripheral shielding gate electrodes PSG1, and second peripheral shielding gate electrodes PSG2 may include a conductive material. For example, the conductive material may include at least one of a conductive semiconductor material, a conductive metal nitride, a conductive metal silicon nitride, a metal carbonitride, a conductive metal silicide, a conductive metal oxide, a 2D material, or a metal.

In some embodiments, the first cell shielding gate electrodes SG1 may include a conductive material having a different work function from that of the cell back gate electrodes BG, and the second cell shielding gate electrodes SG2 may include a conductive material having a different work function from that of the first wordlines WL1 and second wordlines WL2. For example, each of the first cell shielding gate electrodes SG1 and second cell shielding gate electrodes SG2 may include a material having a higher work function than that of the first wordlines WL1, second wordlines WL2, and cell back gate electrodes BG. In this example, for example, the same voltage may be applied to the first cell shielding gate electrodes SG1 and the cell back gate electrodes BG, and the same voltage may be applied to the second cell shielding gate electrodes SG2, the first wordlines WL1, and the second wordlines WL2. The first peripheral shielding gate electrodes PSG1 may include a conductive material having a different work function from that of the peripheral back gate electrodes PBG, and the second peripheral shielding gate electrodes PSG2 may include a conductive material having a different work function from that of the first peripheral gate electrodes GE1 and second peripheral gate electrodes GE2. For example, each of the first peripheral shielding gate electrodes PSG1 and second peripheral shielding gate electrodes PSG2 may include a material having a higher work function than that of the first peripheral gate electrodes GE1, second peripheral gate electrodes GE2, and peripheral back gate electrodes PBG. In this example, the same voltage may be applied to the first peripheral shielding gate electrodes PSG1 and the peripheral back gate electrodes PBG, and the same voltage may be applied to the second peripheral shielding gate electrodes PSG2, the first peripheral gate electrodes GE1, and the second peripheral gate electrodes GE2.

The back gate capping patterns 115 may be positioned between the bitlines BL and the cell back gate electrodes BG, and between the peripheral wirings 160P and the peripheral back gate electrodes PBG. Each of the back gate capping patterns 115 may be positioned between adjacent first and second cell active patterns AP1 and AP2 in the second direction DR2, and between adjacent first and second peripheral active patterns PAP1 and PAP2 in the second direction DR2. The back gate capping patterns 115 may extend in the first direction DR1 in parallel with the cell back gate electrodes BG and in parallel with the peripheral back gate electrodes PBG. The back gate capping patterns 115 may be positioned on the bottom surfaces of the cell back gate electrodes BG and peripheral back gate electrodes PBG.

The first shielding isolation patterns 121 may be positioned between the cell back gate electrodes BG and the first cell shielding gate electrodes SG1, and between the peripheral back gate electrodes PBG and the first peripheral shielding gate electrodes PSG1. The first shielding capping patterns 111 may be positioned on the top surfaces of the first cell shielding gate electrodes SG1 and first peripheral shielding gate electrodes PSG1 and may cover the first cell shielding gate electrodes SG1 and the first peripheral shielding gate electrodes PSG1. The first shielding capping patterns 111 may be positioned between the first cell shielding gate electrodes SG1 and the first interlayer insulating film 271, and between the first peripheral shielding gate electrodes PSG1 and the first interlayer insulating film 271.

Each of the first shielding capping patterns 111 may be positioned between adjacent first and second cell active patterns AP1 and AP2 in the second direction DR2, and between adjacent first and second peripheral active patterns PAP1 and PAP2 in the second direction DR2. The first shielding capping patterns 111 may be positioned on the top surfaces of the first cell shielding gate electrodes SG1 and first peripheral shielding gate electrodes PSG1. The first shielding capping patterns 111 may extend in the first direction DR1 in parallel with the cell back gate electrodes BG. The first shielding capping patterns 111 may also extend in the first direction DR1 in parallel with the peripheral back gate electrodes PBG.

The cell back gate insulating patterns 113 may be positioned between the cell back gate electrodes BG and the first cell active patterns AP1, between the cell back gate electrodes BG and the second cell active patterns AP2, between the first cell shielding gate electrodes SG1 and the first cell active patterns AP1, and between the first cell shielding gate electrodes SG1 and the second cell active patterns AP2. The cell back gate insulating patterns 113 may extend along the first sidewalls SS1 of the first cell active patterns AP1 and along the second sidewalls SS2 of the second cell active patterns AP2.

The peripheral back gate insulating patterns 113P may be positioned between the peripheral back gate electrodes PBG and the first peripheral active patterns PAP1, between the peripheral back gate electrodes PBG and the second peripheral active patterns PAP2, between the first peripheral shielding gate electrodes PSG1 and the first peripheral active patterns PAP1, and between the first peripheral shielding gate electrodes PSG1 and the second peripheral active patterns PAP2. The peripheral back gate insulating patterns 113P may extend along the first sidewalls SS1 of the first peripheral active patterns PAP1 and along the second sidewalls SS2 of the second peripheral active patterns PAP2.

The gate capping patterns 145 may be positioned on the bottom surfaces of the first wordlines WL1 and second wordlines WL2 and on the bottom surfaces of the first peripheral gate electrodes GE1 and second peripheral gate electrodes GE2. The gate separation patterns GSS may be positioned on the bitlines BL and the peripheral wirings 160P. Each of the gate separation patterns GSS may be positioned between adjacent first and second wordlines WL1 and WL2 in the second direction DR2 and between adjacent first and second peripheral gate electrodes GE1 and GE2 in the second direction DR2. The gate separation patterns GSS may extend in the first direction DR1 between the first wordlines WL1 and the second wordlines WL2 and between the first peripheral gate electrodes GE1 and the second peripheral gate electrodes GE2.

The gate separation patterns GSS may be located between the second shielding capping patterns 143 and the gate capping patterns 145. The top surfaces of the gate separation patterns GSS facing the first interlayer insulating film 271 and side surfaces adjacent to the top surfaces may be covered by the second shielding capping patterns 143, and the bottom surfaces of the gate separation patterns GSS opposite to the top surfaces in the third direction DR3 and side surfaces adjacent to the bottom surfaces may be covered by the gate capping patterns 145.

Adjacent first and second wordlines WL1 and WL2 in the second direction DR2, and adjacent first and second peripheral gate electrodes GE1 and GE2 in the second direction DR2, may each be separated by the gate separation patterns GSS, the second shielding capping patterns 143, and the gate capping patterns 145.

The first wordlines WL1 may be positioned between the gate separation patterns GSS and the first cell active patterns AP1. The second wordlines WL2 may be positioned between the gate separation patterns GSS and the second cell active patterns AP2. The first peripheral gate electrodes GE1 may be positioned between the gate separation patterns GSS and the first peripheral active patterns PAP1. The second peripheral gate electrodes GE2 may be positioned between the gate separation patterns GSS and the second peripheral active patterns PAP2.

The gate separation patterns GSS and the gate capping patterns 145 may include an insulating material. Each of the gate separation patterns GSS and gate capping patterns 145 may include, for example, silicon oxide, silicon nitride, or any combination thereof. For example, the gate separation patterns GSS may include silicon oxide, and the gate capping patterns 145 may include silicon nitride.

The second shielding isolation patterns 122 may be positioned between the first wordlines WL1/the second wordlines WL2 and the second cell shielding gate electrodes SG2, and between the first peripheral gate electrodes GE1/the second peripheral gate electrodes GE2 and the second peripheral shielding gate electrodes PSG2. The second shielding isolation patterns 122 may be positioned on the top surfaces of the second cell shielding gate electrodes SG2 and the second peripheral shielding gate electrodes PSG2 and may cover the second cell shielding gate electrodes SG2 and the second peripheral shielding gate electrodes PSG2.

The second shielding capping patterns 143 may cover the top surfaces and both side surfaces of the gate separation patterns GSS located at a higher level than the second cell shielding gate electrodes SG2, and the top surfaces and both side surfaces of the gate separation patterns GSS located at a higher level than the second peripheral shielding gate electrodes PSG2. The second shielding capping patterns 143 may be positioned between the second cell shielding gate electrodes SG2 and the contact patterns BC, between the second peripheral shielding gate electrodes PSG2 and the conductive patterns CP, and between the gate separation patterns GSS and the first interlayer insulating film 271.

Each of the first shielding capping patterns 111, first shielding isolation patterns 121, second shielding capping patterns 143, and second shielding isolation patterns 122 may include an insulating material. Each of the first shielding capping patterns 111, first shielding isolation patterns 121, second shielding capping patterns 143, and second shielding isolation patterns 122 may include, for example, a silicon oxide film, a silicon oxynitride film, or a silicon nitride film, but is not limited thereto.

The cell gate insulating patterns GOX may be positioned between the first wordlines WL1 and the first cell active patterns AP1, between the second cell shielding gate electrodes SG2 and the first cell active patterns AP1, between the second wordlines WL2 and the second cell active patterns AP2, and between the second cell shielding gate electrodes SG2 and the second cell active patterns AP2. The cell gate insulating patterns GOX may extend in the first direction DR1 in parallel with the first wordlines WL1 and the second wordlines WL2. The cell gate insulating patterns GOX may extend along the second sidewalls SS2 of the first cell active patterns AP1 and along the first sidewalls SS1 of the second cell active patterns AP2.

The peripheral gate insulating patterns PGOX may be positioned between the first peripheral gate electrodes GE1 and the first peripheral active patterns PAP1, and between the second peripheral shielding gate electrodes PSG2 and the second peripheral active patterns PAP2. The peripheral gate insulating patterns PGOX may extend in the first direction DR1 in parallel with the first peripheral gate electrodes GE1 and the second peripheral gate electrodes GE2. The peripheral gate insulating patterns PGOX may extend along the second sidewalls SS2 of the first peripheral active patterns PAP1 and along the second sidewalls SS2 of the second peripheral active patterns PAP2.

Each of the cell back gate insulating patterns 113, cell gate insulating patterns GOX, peripheral back gate insulating patterns 113P, and peripheral gate insulating patterns PGOX may include a silicon oxide film, a silicon oxynitride film, a high-k dielectric film having a dielectric constant higher than that of silicon oxide, or a combination thereof.

Cell transistor structures CTS may each include a pair of adjacent right and left cell transistors CTR(R) and CTR(L). Each of the right cell transistors CTR(R) may include a first wordline WL1 and a first cell active pattern AP1 that are adjacent to one another. The first dopant regions SD1 and second dopant regions SD2 of the first cell active patterns AP1 may correspond to the first source/drain electrodes and second source/drain electrodes, respectively, of the right cell transistors CTR(R), and the channel regions CH of the first cell active patterns AP1 may correspond to the channel regions of the right cell transistors CTR(R). Each of the left cell transistors CTR(L) may include a second wordline WL2 and a second cell active pattern AP2 that are adjacent to one another. The first dopant regions SD1 and second dopant regions SD2 of the second cell active patterns AP2 may correspond to the first source/drain electrodes and second source/drain electrodes, respectively, of the left cell transistors CTR(L), and the channel regions CH of the second cell active patterns AP2 may correspond to the channel regions of the left cell transistors CTR(L).

In some embodiments, each of the right cell transistors CTR(R) and left cell transistors CTR(L) may further include at least one of a cell back gate electrode BG, a first cell shielding gate electrode SG1, or a second cell shielding gate electrode SG2.

First peripheral transistor structures PTS1 may each include a pair of adjacent right and left peripheral transistors PTR1(R) and PTR1(L). Each of the right peripheral transistors PTR1(R) may include a first peripheral gate electrode GE1 and a first peripheral active pattern PAPI that are adjacent to one another. The first dopant regions SD1 and second dopant regions SD2 of the first peripheral active patterns PAP1 may correspond to the first source/drain electrodes and second source/drain electrodes of the right peripheral transistors PTR1(R), and the channel regions CH of the first peripheral active patterns PAP1 may correspond to the channel regions of the right peripheral transistors PTR1(R). Each of the left peripheral transistors PTR1(L) may include a second peripheral gate electrode GE2 and a second peripheral active pattern PAP2 that are adjacent to one another. The first dopant regions SD1 and second dopant regions SD2 of the second peripheral active patterns PAP2 may correspond to the first source/drain electrodes and second source/drain electrodes, respectively, of the left peripheral transistors PTR1(L), and the channel regions CH of the second peripheral active patterns PAP2 may correspond to the channel regions of the left peripheral transistors PTR1(L).

In some embodiments, each of the right peripheral transistors PTR1(R) and left peripheral transistors PTR1(L) may further include at least one of a peripheral back gate electrode PBG, a first peripheral shielding gate electrode PSG1, or a second peripheral shielding gate electrode PSG2.

The semiconductor memory device according to some embodiments may include N-type first peripheral transistor structures PTS1(N) and P-type first peripheral transistor structures PTS1(P). The N-type first peripheral transistor structures PTS1(N) and the P-type first peripheral transistor structures PTS1(P) may form complementary metal-oxide-semiconductor (CMOS) circuitry. The first dopant regions SD1 and second dopant regions SD2 of the N-type first peripheral transistor structures PTS1(N) may be doped with an N-type dopant. The channel regions CH of the N-type first peripheral transistor structures PTS1(N) may be undoped or may be doped with a P-type dopant. The first dopant regions SD1 and second dopant regions SD2 of the P-type first peripheral transistor structures PTS1(P) may be doped with a P-type dopant. The channel regions CH of the P-type first peripheral transistor structures PTS1(P) may be undoped or may be doped with an N-type dopant.

The voltages applied to the first peripheral shielding gate electrodes PSG1 and second peripheral shielding gate electrodes PSG2 included in the N-type first peripheral transistor structures PTS1(N) may differ from the voltages applied to the first peripheral shielding gate electrodes PSG1 and second peripheral shielding gate electrodes PSG2 included in the P-type first peripheral transistor structures PTS1(P). The first peripheral gate electrodes GE1 and second peripheral gate electrodes GE2 included in the N-type first peripheral transistors structures PTS1(N) may be referred to as first sub-gate electrodes, and the first peripheral gate electrodes GE1 and second peripheral gate electrodes GE2 included in the P-type first peripheral transistor structures PTS1(P) may be referred to as second sub-gate electrodes.

The first interlayer insulating film 271 may be positioned on the first cell active patterns AP1 and the second cell active patterns AP2 and on the first peripheral active patterns PAP1 and the second peripheral active patterns PAP2. The contact patterns BC, the landing pads LP, the conductive patterns CP, and the electrode pads EP may be positioned in the first interlayer insulating film 271.

The contact patterns BC may be respectively connected to the first cell active patterns AP1 and the second cell active patterns AP2. The contact patterns BC may be connected to the second surfaces of the first cell active patterns AP1 and second cell active patterns AP2. The landing pads LP may be positioned on the contact patterns BC.

In some embodiments, the conductive patterns CP may be respectively connected to the first peripheral active patterns PAP1 and the second peripheral active patterns PAP2. The conductive patterns CP may be connected to the second surfaces of the first peripheral active patterns PAP1 and second peripheral active patterns PAP2. The electrode pads EP may be positioned on the conductive patterns CP.

From a planar perspective, the contact patterns BC, the landing pads LP, the conductive patterns CP, and the electrode pads EP may each have various shapes such as circular, elliptical, rectangular, square, rhombic, or hexagonal. The contact patterns BC, the landing pads LP, the conductive patterns CP, and the electrode pads EP may each include a conductive material. Each of the contact patterns BC, landing pads LP, conductive patterns CP, and electrode pads EP may include at least one of doped polysilicon, a conductive metal nitride, a conductive metal silicon nitride, a metal carbonitride, a conductive metal silicide, a conductive metal oxide, a 2D material, or a metal. The conductive patterns CP may include the same material as the contact patterns BC, and the electrode pads EP may include the same material as the landing pads LP. The conductive patterns CP may include a metal, a silicon film doped with a dopant, SiGe, or SiC. Here, the dopant doped in each of the conductive patterns CP may be of the same conductivity type as the dopant doped in the first dopant regions SD1 and second dopant regions SD2 of the first peripheral active patterns PAP1 and second peripheral active patterns PAP2.

The cell capacitors DSP1 may be positioned on the landing pads LP, respectively.

The cell capacitors DSP1 may be electrically connected to the first cell active patterns AP1 and the second cell active patterns AP2, respectively. The cell capacitors DSP1 may be arranged in a matrix form along the first and second directions DR1 and DR2. The cell capacitors DSP1 may entirely or partially overlap the landing pads LP in the third direction DR3. The cell capacitors DSP1 may entirely or partially contact the top surfaces of the landing pads LP.

The peripheral capacitors DSP2 may be positioned on the electrode pads EP. The peripheral capacitors DSP2 may be positioned on the conductive patterns CP.

In one example, each of the cell capacitors DSP1 and peripheral capacitors DSP2 may include storage electrodes 251, a plate electrode 255, and a capacitor dielectric film 253 interposed between the storage electrodes 251 and the plate electrode 255. From a planar perspective, the storage electrodes 251 may have various shapes such as circular, elliptical, rectangular, square, rhombic, or hexagonal. For example, the storage electrodes 251 of each of the cell capacitors DSP1 may contact the landing pads LP.

For example, the peripheral capacitors DSP2 may be power capacitors. The peripheral capacitors DSP2 may be electrically connected to the first peripheral transistors PTR1. One electrode pad EP may contact multiple storage electrodes 251 of a corresponding peripheral capacitor DSP2. For example, in the peripheral circuit area PCR, portions of the cell connection structure 360 overlapping the first peripheral transistors PTR1 may constitute a backside power delivery network (PDN) layer.

The second interlayer insulating film 272 may be positioned on the first interlayer insulating film 271. The second interlayer insulating film 272 may cover the cell capacitors DSP1 and the peripheral capacitors DSP2. The first and second interlayer insulating films 271 and 272 include an insulating material. The first and second interlayer insulating films 271 and 272 are illustrated as single layers, but are not limited thereto.

The connection pads 280 may be positioned on the second interlayer insulating film 272. The connection pad plugs 282 may be positioned in the second interlayer insulating film 272. The connection pad plugs 282 may connect the connection pads 280 to the cell capacitor DSP1s. The connection pad plugs 282 may connect the connection pads 280 to the peripheral capacitors DSP2. Each of the connection pads 280 and connection pad plugs 282 may include at least one of a conductive metal nitride, a conductive metal silicon nitride, a metal carbonitride, a conductive metal oxide, or a metal.

The cell interlayer insulating film 365 may be positioned on the rear surfaces of the bitlines BL and on the rear surfaces of the peripheral wirings 160P. The cell interlayer insulating film 365 may cover the bitlines BL and the peripheral wirings 160P. The cell interlayer insulating film 365 may include an insulating material. The bitline contacts BLC, the peripheral contacts 341a, the cell wiring lines 341b, and the cell connection structure 360 may be positioned in the cell interlayer insulating film 365.

The bitline contacts BLC may be connected to the bitlines BL. The peripheral contacts 341a may be connected to the peripheral wirings 160P. Various contacts may be positioned in the cell interlayer insulating film 365, such as contacts connected to the first wordlines WL1 and the second wordlines WL2, contacts connected to the cell back gate electrodes BG, contacts connected to the first cell shielding gate electrodes SG1, contacts connected to the second cell shielding gate electrodes SG2, contacts connected to the first peripheral gate electrodes GE1 and the second peripheral gate electrodes GE2, contacts connected to the peripheral back gate electrodes PBG, contacts connected to the first peripheral shielding gate electrodes PSG1, contacts connected to the second peripheral shielding gate electrodes PSG2, and contacts connected to the cell connection structure 360. The contacts connected to the cell connection structure 360 may be connected to the connection plugs in the first and second interlayer insulating films 271 and 272 and may thus be connected to the connection pads 280. The cell wiring lines 341b may be connected to the bitline contacts BLC.

The cell wiring lines 341b may be connected to the peripheral contacts 341a. The cell wiring lines 341b may be the wiring lines closest to the bitlines BL or the peripheral wirings 160P.

The cell connection structure 360 may be connected to the first peripheral transistors PTR1 and the memory cells. The cell connection structure 360 may be positioned on the cell wiring lines 341b. The cell connection structure 360 may be connected to the cell wiring lines 341b. The cell connection structure 360 may include cell connection wirings (361b and 362b) and cell connection vias (361a and 362a). The cell connection structure 360 is illustrated as including multiple cell connection wirings (361b and 362b) positioned on different metal levels, but is not limited thereto. Each of the bitline contacts BLC, peripheral contacts 341a, cell wiring lines 341b, cell connection wirings (361b and 362b), and cell connection vias (361a and 362a) may include a conductive material.

The peripheral circuit structure PS may include the second peripheral transistors PTR2, a peripheral interlayer insulating film 265, peripheral contact plugs 241a, peripheral wiring lines 241b, and a peripheral connection structure 260.

The peripheral interlayer insulating film 265 may be positioned on the substrate 100. The peripheral interlayer insulating film 265 may cover the second peripheral transistors PTR2 and the front surface of the substrate 100. The peripheral interlayer insulating film 265 may include an insulating material. The peripheral contact plugs 241a, the peripheral wiring lines 241b, and the peripheral connection structure 260 may be positioned in the peripheral interlayer insulating film 265.

The peripheral contact plugs 241a may be connected to the source/drain regions of the second peripheral transistors PTR2, which may be, for example, regions of the substrate 100 doped with impurities. Contacts connected to first peripheral conductive patterns 223 and second peripheral conductive patterns 225 of the second peripheral transistors PTR2 may be positioned in the peripheral interlayer insulating film 265. The peripheral wiring lines 241b may be connected to the peripheral contact plugs 241a. The peripheral wiring lines 241b may be the wiring lines closest to the second peripheral transistors PTR2.

The peripheral connection structure 260 may be connected to the second peripheral transistors PTR2. The peripheral connection structure 260 may be positioned on the peripheral wiring lines 241b. The peripheral connection structure 260 may be connected to the peripheral wiring lines 241b. The peripheral connection structure 260 may include peripheral connection wirings (261b and 262b) and peripheral connection vias (261a and 262a). The peripheral connection structure 260 is illustrated as including multiple peripheral connection wirings (261b and 262b) positioned on different metal levels, but is not limited thereto. Each of the peripheral contact plugs 241a, peripheral wiring lines 241b, peripheral connection wirings (261b and 262b), and peripheral connection vias (261a and 262a) may include a conductive material.

In some embodiments, the cell structure CS and the peripheral circuit structure PS may be bonded using a Cu-to-Cu (C2C) wafer bonding method. The peripheral circuit structure PS may further include peripheral bonding pad plugs 263 and peripheral bonding pads BP1 in the peripheral interlayer insulating film 265. The peripheral bonding pad plugs 263 may be positioned on the peripheral connection structure 260. The peripheral bonding pads BP1 may be positioned on the peripheral bonding pad plugs 263. The peripheral bonding pad plugs 263 may connect the peripheral bonding pads BP1 and the peripheral connection structure 260. The cell structure CS may further include cell bonding pad plugs 363 and cell bonding pads BP2 in the cell interlayer insulating film 365. The cell bonding pad plugs 363 may be positioned on the cell connection structure 360. The cell bonding pads BP2 may be positioned on the cell bonding pad plugs 363. The cell bonding pad plugs 363 may connect the cell bonding pads BP2 and the cell connection structure 360. The peripheral bonding pads BP1 may be connected to the cell bonding pads BP2. The peripheral bonding pads BP1 may be bonded to the cell bonding pads BP2, and the peripheral interlayer insulating film 265 may be bonded to the cell interlayer insulating film 365. Accordingly, the cell structure CS and the peripheral circuit structure PS may be electrically connected.

The substrate 100 may include a front surface on which the second peripheral transistors PTR2 are positioned and a rear surface opposite to the front surface in the third direction DR3. In one example, the front surface of the substrate 100 may face the cell structure CS. In another example, the rear surface of the substrate 100 may face the cell structure CS. In one example, the cell transistors CTR may be positioned between the cell capacitors DSP1 and the substrate 100. In another example, the cell capacitors DSP1 may be positioned between the cell transistors CTR and the substrate 100.

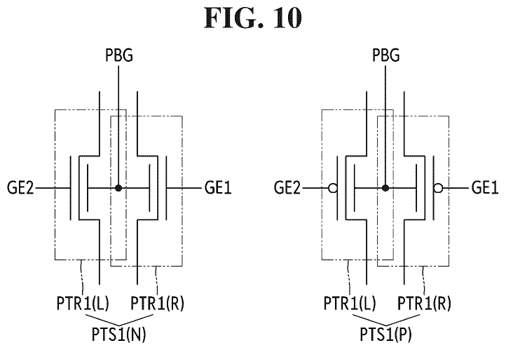

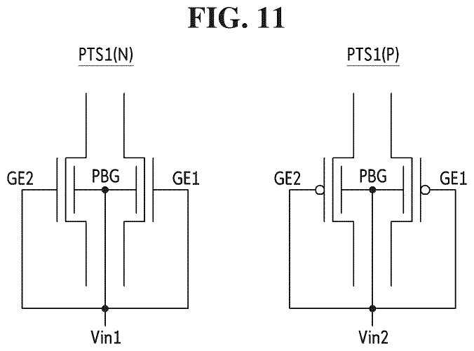

FIGS. 10 and 11 are exemplary circuit diagrams of the first peripheral transistor structures in FIGS. 8 and 9. For convenience of explanation, the following description will primarily focus on differences from the embodiments of FIGS. 1 through 9.

Referring to FIGS. 8, 9, 10, and 11, an N-type first peripheral transistor structure PTS1(N) may include two NMOS transistors PTR1(L) and PTR1(R), which are VCTs adjacent to one another and share a single peripheral back gate electrode PBG. A P-type first peripheral transistor structure PTS1(P) may include two PMOS transistors PTR1(L) and PTR1(R), which are VCTs adjacent to one another and share a single peripheral back gate electrode PBG.

Referring to FIG. 11, first and second peripheral gate electrodes GE1 and GE2 and the peripheral back gate electrode PBG of the N-type first peripheral transistor structure PTS1(N) may be connected together with a first input voltage Vin1 applied in common thereto. First and second peripheral gate electrodes GE1 and GE2 and the peripheral back gate electrode PBG of the P-type first peripheral transistor structure PTS1(P) may be connected together with a second input voltage Vin2 applied in common thereto. The N-type first peripheral transistor structure PTS1(N) and the P-type first peripheral transistor structure PTS1(P) may each have a double gate structure or a gate-all-around structure.

Alternatively, different input voltages may be applied to the first and second peripheral gate electrodes GE1 and GE2 and the peripheral back gate electrode PBG of the N-type first peripheral transistor structure PTS1(N), and different input voltages may be applied to the first and second peripheral gate electrodes GE1 and GE2 and the peripheral back gate electrode PBG of the P-type first peripheral transistor structure PTS1(P). The N-type and P-type first peripheral transistor structures PTS1(N) and PTS1(P) may each have an independent double gate structure.

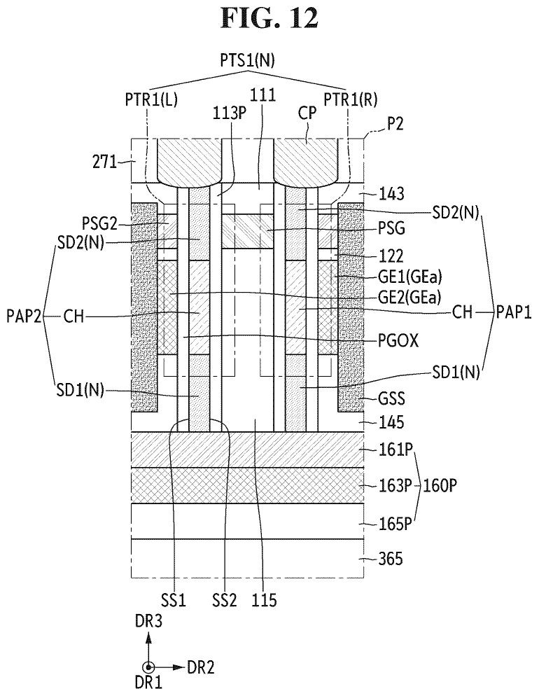

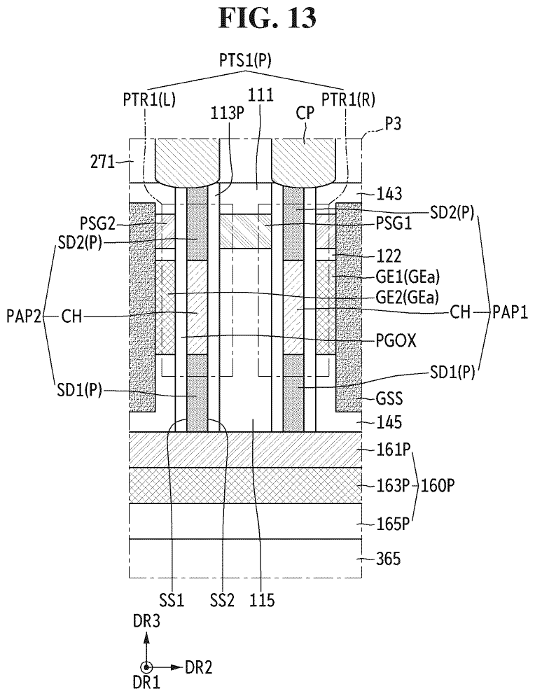

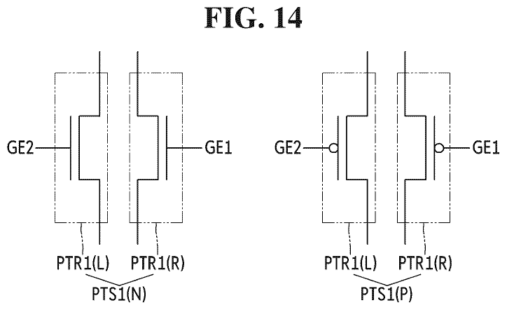

FIG. 12 is an enlarged cross-sectional view of portion P2 in FIG. 5. FIG. 13 is an enlarged cross-sectional view of portion P3 in FIG. 5. FIG. 14 is an exemplary circuit diagram of first peripheral transistor structures in FIGS. 12 and 13. For convenience of explanation, the following description will primarily focus on differences from the embodiments of FIGS. 1 through 11.

Referring to FIGS. 12 through 14, in the semiconductor memory device according to some embodiments, the peripheral back gate electrodes PBG and the second shielding isolation patterns 122 of FIGS. 1 through 9 may be omitted. N-type and P-type first peripheral transistor structures PTS1(N) and PTS1(P) of FIGS. 12 through 14 may each have a single gate structure.

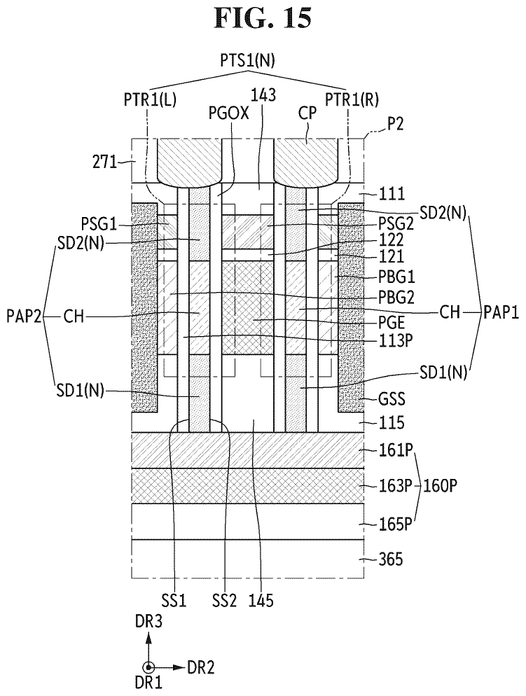

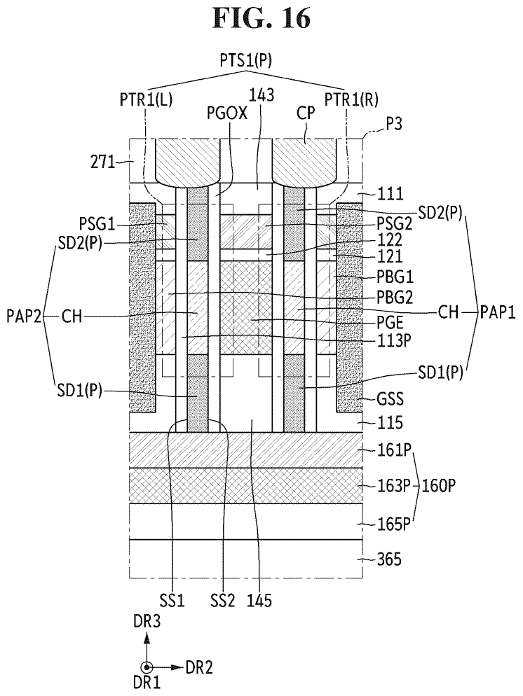

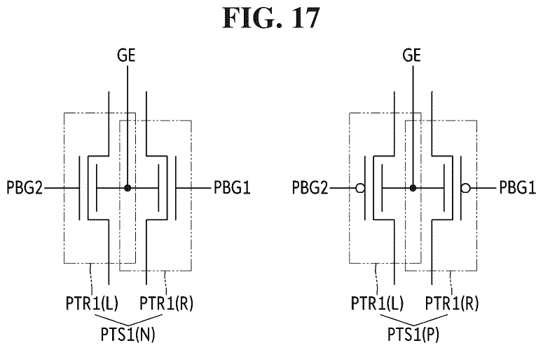

FIG. 15 is an enlarged cross-sectional view of portion P2 in FIG. 5. FIG. 16 is an enlarged cross-sectional view of portion P3 in FIG. 5. FIG. 17 is an exemplary circuit diagram of first peripheral transistor structures in FIGS. 15 and 16. For convenience of explanation, the following description will primarily focus on differences from the embodiments of FIGS. 1 through 14.

Referring to FIGS. 15 and 16, a first peripheral back gate electrode PBG1, a second peripheral back gate electrode PBG2 and a peripheral gate electrode GE may be formed at positions corresponding to a first peripheral gate electrode GE1, a second peripheral gate electrode GE2, and a peripheral back gate electrode PBG, respectively, in FIGS. 1 through 11.

Referring to FIGS. 15 through 17, in the in the semiconductor memory device according to some embodiments, the peripheral back gate electrode PBG may be positioned on a second sidewall SS2 of a first peripheral active pattern PAP1. The second peripheral back gate electrode PBG2 may be positioned on a first sidewall SS1 of a second peripheral active pattern PAP2. The first and second peripheral active patterns PAP1 and PAP2 may be positioned between adjacent first and second peripheral back gate electrodes PBG1 and PBG2 in the second direction DR2.

The peripheral gate electrode GE may be positioned between the first and second peripheral active patterns PAP1 and PAP2 adjacent in the second direction DR2. The peripheral gate electrode GE may be positioned between the first sidewall SS1 of the first peripheral active pattern PAP1 and the second sidewall SS2 of the second peripheral active pattern PAP2. The peripheral gate electrode GE may be positioned on the first sidewall SS1 of the first peripheral active pattern PAP1 and the second sidewall SS2 of the second peripheral active pattern PAP2. A second shielding isolation pattern 122 may be positioned between the peripheral gate electrode GE and the second peripheral shielding gate electrode PSG2. A gate capping pattern 145 may be positioned on the bottom surface of the peripheral gate electrode GE.

An N-type first peripheral transistor structure PTS1(N) may include two NMOS left and right peripheral transistors PTR1(L) and PTR1(R), which are adjacent to one another and share a single peripheral gate electrode GE. A P-type first peripheral transistor structure PTS1(P) may include two PMOS left and right peripheral transistors PTR1(L) and PTR1(R), which are adjacent to one another and share a single peripheral gate electrode GE. These right peripheral transistors PTR1(R) and left peripheral transistors PTR1(L) may each include the peripheral gate electrode GE and the first and second peripheral back gate electrodes PBG1 and PBG2.

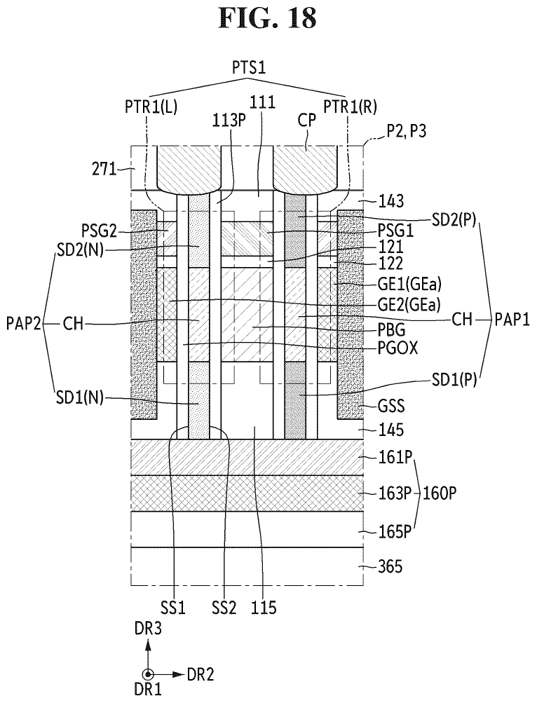

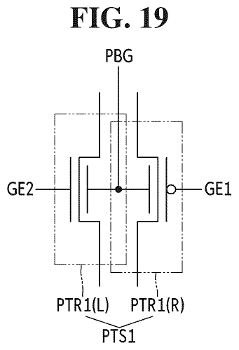

FIG. 18 is an enlarged cross-sectional view of portion P2 or P3 in FIG. 5. FIG. 19 is an exemplary circuit diagram of a first peripheral transistor structure in FIG. 18. For convenience of explanation, the following description will primarily focus on differences from the embodiments of FIGS. 1 through 17.

Referring to FIGS. 18 and 19, in the semiconductor memory device according to some embodiments, first and second dopant regions SD1 and SD2 of a first peripheral active pattern PAP1 may be doped with a p-type dopant, and first and second dopant regions SD1 and SD2 of a second peripheral active pattern PAP2 may be doped with an n-type dopant. A left peripheral transistors PTR1(L) may be an NMOS transistor, and a right peripheral transistor PTR1(R) may be a PMOS transistor. The left and right peripheral transistors PTR1(L) and PTR1(R) may share a single peripheral back gate electrode PBG. In some embodiments, the peripheral back gate electrodes PBG may be grounded.

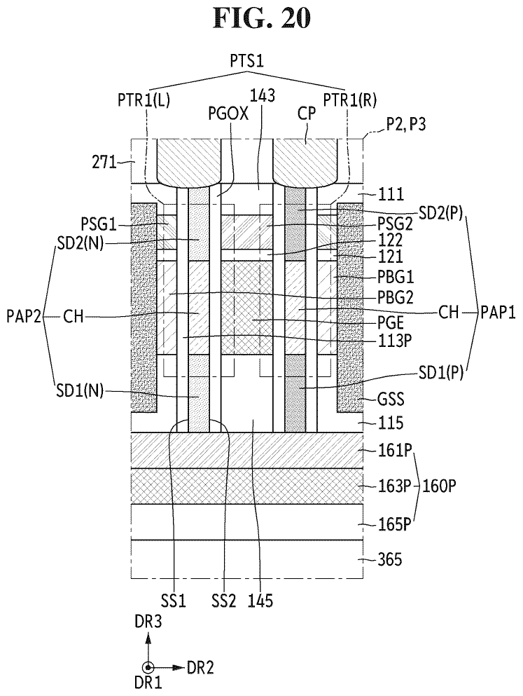

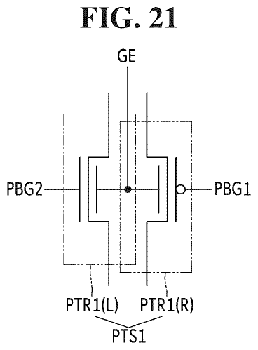

FIG. 20 is an enlarged cross-sectional view of portion P2 or P3 of FIG. 5. FIG. 21 is an exemplary circuit diagram of a first peripheral transistor structure in FIG. 20. For convenience of explanation, the following description will primarily focus on differences from the embodiments of FIGS. 1 through 19.

Referring to FIG. 20, a first peripheral back gate electrode PBG1, a second peripheral back gate electrode PBG2, and a peripheral gate electrode GE may be formed at positions corresponding to a first peripheral gate electrode GE1, a second peripheral gate electrode GE2, and a peripheral back gate electrode PBG, respectively, in FIGS. 1 through 11.

Referring to FIGS. 20 and 21, in the semiconductor memory device according to some embodiments, first and second dopant regions SD1 and SD2 of a first peripheral active patterns PAP1 may be doped with a p-type dopant, and first and second dopant regions SD1 and SD2 of a second peripheral active patterns PAP2 may be doped with an n-type dopant. A left peripheral transistor PTR1(L) may be an NMOS transistor, and a right peripheral transistor PTR1(R) may be a PMOS transistor. The left and right peripheral transistors PTR1(L) and PTR1(R) may share a single peripheral gate electrode GE.

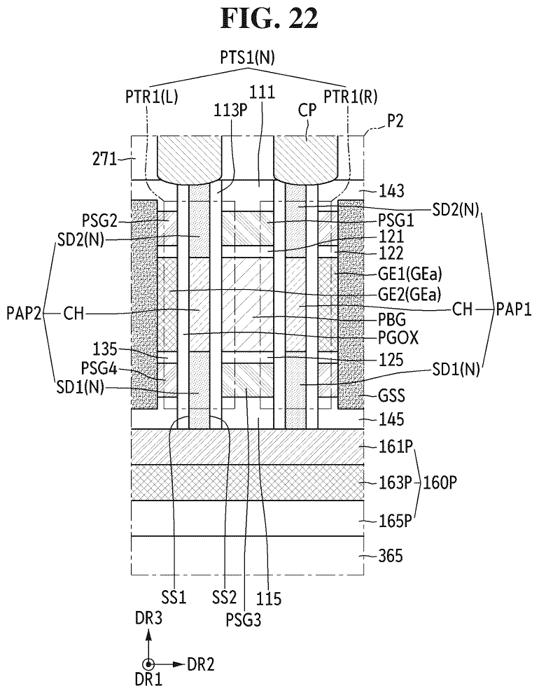

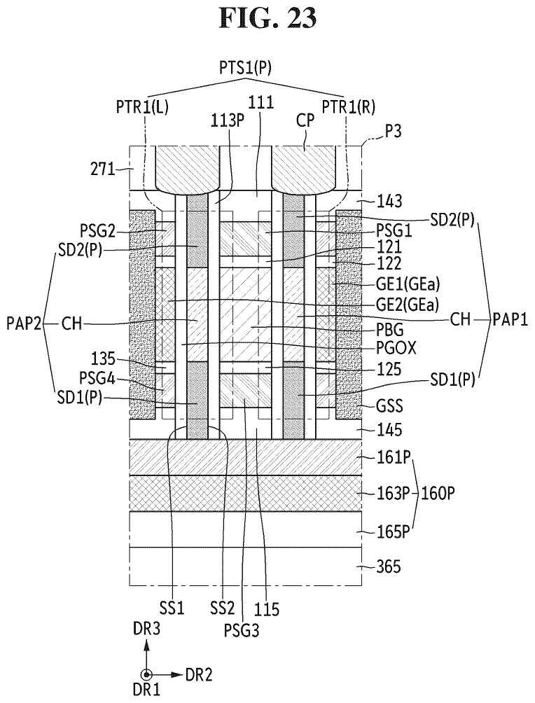

FIG. 22 is an enlarged cross-sectional view of portion P2 in FIG. 5. FIG. 23 is an enlarged cross-sectional view of portion P3 in FIG. 5. For convenience of explanation, the following description will primarily focus on differences from the embodiments of FIGS. 1 through 21.

Referring to FIGS. 22 and 23, the semiconductor memory device according to some embodiments may further include a third peripheral shielding gate electrode PSG3 and a fourth peripheral shielding gate electrode PSG4.

A peripheral back gate electrode PBG may be spaced apart from the third peripheral shielding gate electrode PSG3 in the third direction DR3. The third peripheral shielding gate electrode PSG3 may overlap at least a portion of the peripheral back gate electrode PBG in the third direction DR3. The peripheral back gate electrode PBG may be positioned between a first peripheral shielding gate electrode PSG1 and the third peripheral shielding gate electrode PSG3.

First and second peripheral gate electrodes GE1 and GE2 may be spaced apart from the fourth peripheral shielding gate electrode PSG4 in the third direction DR3. The fourth peripheral shielding gate electrode PSG4 may overlap at least portions of the first and second peripheral gate electrodes GE1 and GE2 in the third direction DR3. Each of the first and second peripheral gate electrodes GE1 and GE2 may be positioned between the second and fourth peripheral shielding gate electrodes PSG2 and PSG4.

The third and fourth peripheral shielding gate electrodes PSG3 and PSG4 may be positioned between adjacent first and second peripheral active patterns PAP1 and PAP2 in the second direction DR2. The third peripheral shielding gate electrode PSG3 may be positioned between the first sidewall SS1 of the first peripheral active pattern PAP1 and the second sidewall SS2 of the second peripheral active pattern PAP2. The third peripheral shielding gate electrode PSG3 may be positioned on the first sidewall SS1 of the first peripheral active pattern PAP1 and the second sidewall SS2 of the second peripheral active pattern PAP2. The fourth peripheral shielding gate electrode PSG4 may be positioned on the second sidewall SS2 of the first peripheral active pattern PAP1 and the first sidewall SS1 of the second peripheral active pattern PAP2.

The height of the third and fourth peripheral shielding gate electrodes PSG3 and PSG4 in the third direction DR3 may be less than the height of the first and second peripheral active patterns PAP1 and PAP2. The third and fourth peripheral shielding gate electrodes PSG3 and PSG4 may overlap portions of the first and second peripheral active patterns PAP1 and PAP2 in the second direction DR2. For example, the third and fourth peripheral shielding gate electrodes PSG3 and PSG4 may overlap portions of first dopant regions SD1 of the first and second peripheral active patterns PAP1 and PAP2 in the second direction DR2.

For example, in a plan view, the third peripheral shielding gate electrode PSG3 may have substantially the same shape as the peripheral back gate electrode PBG, and the fourth peripheral shielding gate electrode PSG4 may have substantially the same shape as the first and second peripheral gate electrodes GE1 and GE2. The third peripheral shielding gate electrode PSG3 may extend in the first direction DR1, similar to the peripheral back gate electrode PBG, and the fourth peripheral shielding gate electrode PSG4 may extend in the first direction DR1, similar to the first and second peripheral gate electrodes GE1 and GE2. For example, the peripheral back gate electrode PBG and the third peripheral shielding gate electrode PSG3 may entirely overlap in the third direction DR3, and the first and second peripheral gate electrodes GE1 and GE2 and the fourth peripheral shielding gate electrode PSG4 may entirely overlap in the third direction DR3.

Right and left peripheral transistors PTR1(R) and PTR1(L) may each further include the third and fourth peripheral shielding gate electrodes PSG3 and PSG4.

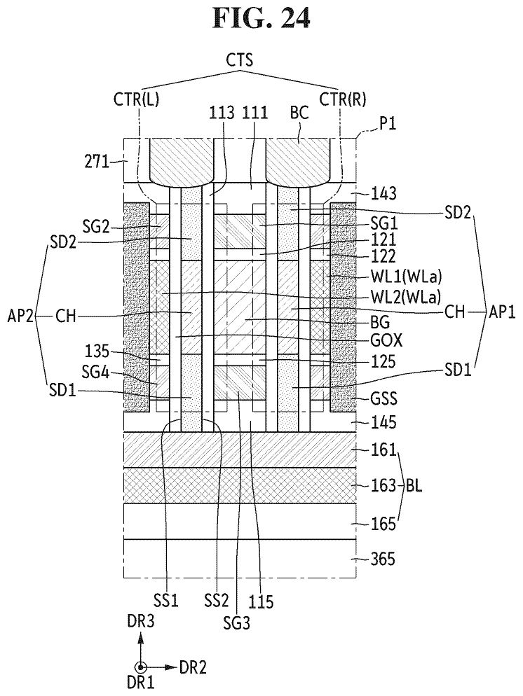

FIG. 24 is an enlarged cross-sectional view of portion P1 in FIG. 5. For convenience of explanation, the following description will primarily focus on differences from the embodiments of FIGS. 1 through 23.

Referring to FIG. 24, the semiconductor memory device according to some embodiments may further include a third cell shielding gate electrode SG3 and a fourth cell shielding gate electrode SG4.

A cell back gate electrode BG may be spaced apart from the third cell shielding gate electrode SG3 in the third direction DR3. The third cell shielding gate electrode SG3 may overlap at least a portion of the cell back gate electrode BG in the third direction DR3. The cell back gate electrode BG may be positioned between a first cell shielding gate electrode SG1 and the third cell shielding gate electrode SG3.

First and second wordlines WL1 and WL2 may be spaced apart from the fourth cell shielding gate electrode SG4 in the third direction DR3. The fourth cell shielding gate electrode SG4 may overlap at least portions of the first and second wordlines WL1 and WL2 in the third direction DR3. Each of the first and second wordlines WL1 and WL2 may be positioned between a second cell shielding gate electrode SG2 and the fourth cell shielding gate electrode SG4.

The third and fourth cell shielding gate electrodes SG3 and SG4 may be positioned between adjacent first and second cell active patterns AP1 and AP2 in the second direction DR2. The third cell shielding gate electrode SG3 may be positioned between a first sidewall SS1 of the first cell active pattern AP1 and a second sidewall SS2 of the second cell active pattern AP2. The third cell shielding gate electrode SG3 may be positioned on the first sidewall SS1 of the first cell active pattern AP1 and the second sidewall SS2 of the second cell active pattern AP2. The fourth cell shielding gate electrode SG4 may be positioned on the second sidewall SS2 of the first cell active pattern AP1 and the first sidewall SS1 of the second cell active pattern AP2.

The height of the third and fourth cell shielding gate electrodes SG3 and SG4 in the third direction DR3 may be less than the height of the first and second cell active patterns AP1 and AP2. The third and fourth cell shielding gate electrodes SG3 and SG4 may overlap portions of the first and second cell active patterns AP1 and AP2 in the second direction DR2. For example, the third and fourth cell shielding gate electrodes SG3 and SG4 may overlap portions of first dopant regions SD1 of the first and second cell active patterns AP1 and AP2 in the second direction DR2.

For example, in a plan view, the third cell shielding gate electrode SG3 may have substantially the same shape as the cell back gate electrode BG, and the fourth cell shielding gate electrode SG4 may have substantially the same shape as the first and second wordlines WL1 and WL2. The third cell shielding gate electrode SG3 may extend in the first direction DR1, similar to the cell back gate electrode BG, and the fourth cell shielding gate electrode SG4 may extend in the first direction DR1, similar to the first and second wordlines WL1 and WL2. For example, the cell back gate electrode BG and the third cell shielding gate electrode SG3 may entirely overlap in the third direction DR3, and the first and second wordlines WL1 and WL2 and the fourth cell shielding gate electrode SG4 may entirely overlap in the third direction DR3.

Each of right and left cell transistors CTR(R) and CTR(L) may further include the third cell shielding gate electrode SG3 and the fourth cell shielding gate electrode SG4.

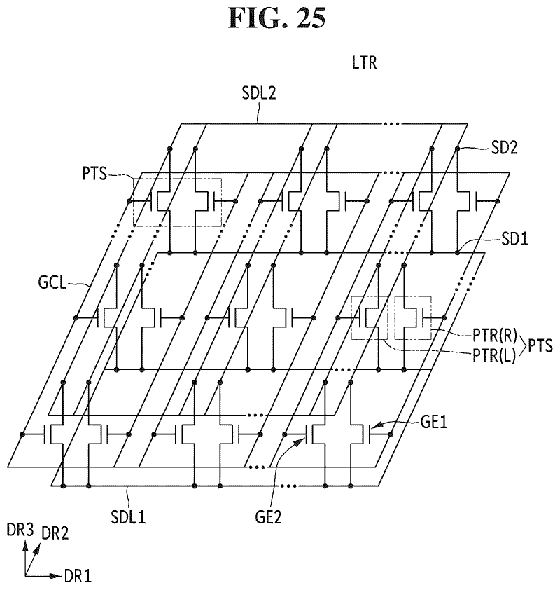

FIG. 25 is a circuit diagram of a logic transistor of a semiconductor memory device according to some embodiments. In the circuit diagram of FIG. 25, peripheral back gate electrodes PBG, first peripheral shielding gate electrodes PSG1, second peripheral shielding gate electrodes PSG2, third peripheral shielding gate electrodes PSG3, and fourth peripheral shielding gate electrodes PSG4 are omitted.

Referring to FIG. 25, in the semiconductor memory device according to some embodiments, a logic transistor LTR may include peripheral transistor structures PTS that are arranged two-dimensionally in M rows and N columns along first and second directions DR1 and DR2, and are electrically connected to one another. Here, M and N may be natural numbers of 2 or greater.

Each of the peripheral transistor structures PTS may include a pair of adjacent left and right peripheral transistors PTR(L) and PTR(R), which may also be referred to as unit transistors. The peripheral transistor structures PTS may correspond to the first peripheral transistor structures PTS1 described with reference to FIGS. 1 through 24. The left peripheral transistors PTR(L) and the right peripheral transistors PTR(R) may correspond to the left peripheral transistors PTR1(L) and the right peripheral transistors PTR1(R), respectively, described with reference to FIGS. 8 through 23.

First dopant regions SD1 of the peripheral transistor structures PTS may be connected by first source/drain connection wirings SDL1. Second dopant regions SD2 of the peripheral transistor structures PTS may be connected by second source/drain connection wirings SDL2. First peripheral gate electrodes GE1 and second peripheral gate electrodes GE2 of the peripheral transistor structures PTS may be connected by gate connection wirings GCL. The peripheral back gate electrodes PBG of the peripheral transistor structures PTS may be connected by back gate electrode connection wirings. The first peripheral shielding gate electrodes PSG1, second peripheral shielding gate electrodes PSG2, third peripheral shielding gate electrodes PSG3, and fourth peripheral shielding gate electrodes PSG4 of the peripheral transistor structures PTS may be connected by first shielding connection wirings, second shielding connection wirings, third shielding connection wirings, and fourth shielding connection wirings, respectively. Voltages may be applied independently to the first peripheral shielding gate electrodes PSG1, the second peripheral shielding gate electrodes PSG2, the third peripheral shielding gate electrodes PSG3, and the fourth peripheral shielding gate electrodes PSG4 via the first shielding connection wirings, the second shielding connection wirings, the third shielding connection wirings, and the fourth shielding connection wirings, respectively.

In some embodiments, an output value of the logic transistor LTR may be equal to a sum of the output values of the unit transistors. The logic transistor LTR may include a plurality of unit transistors that are VCTs, which may increase the output value of the logic transistor LTR while reducing the horizontal size of the logic transistor LTR.

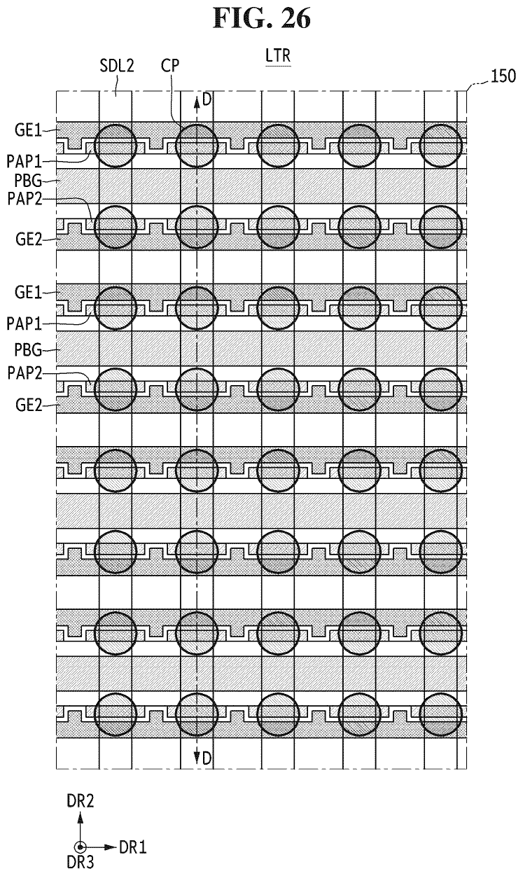

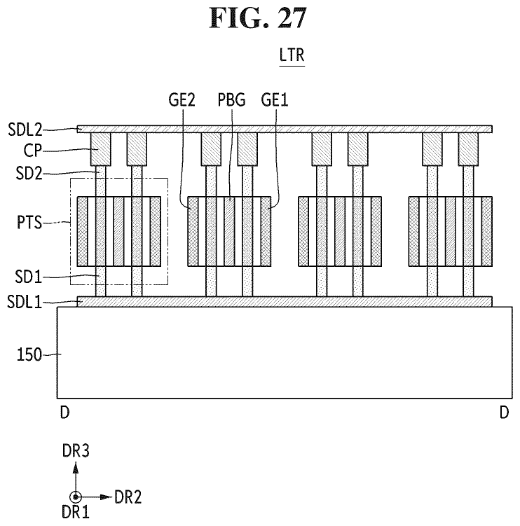

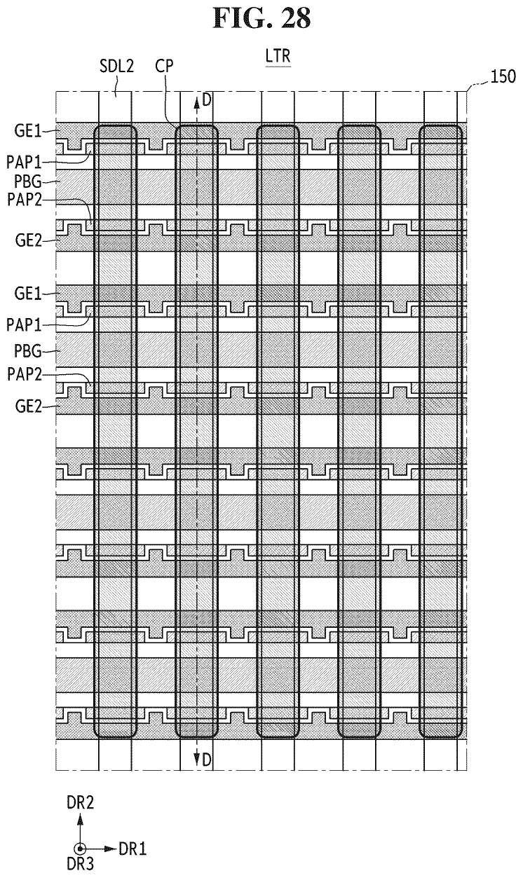

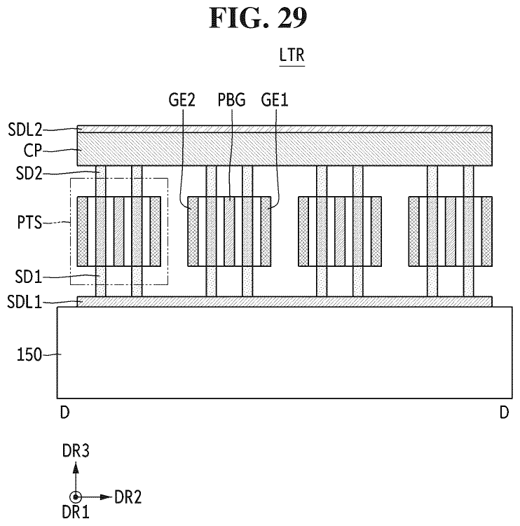

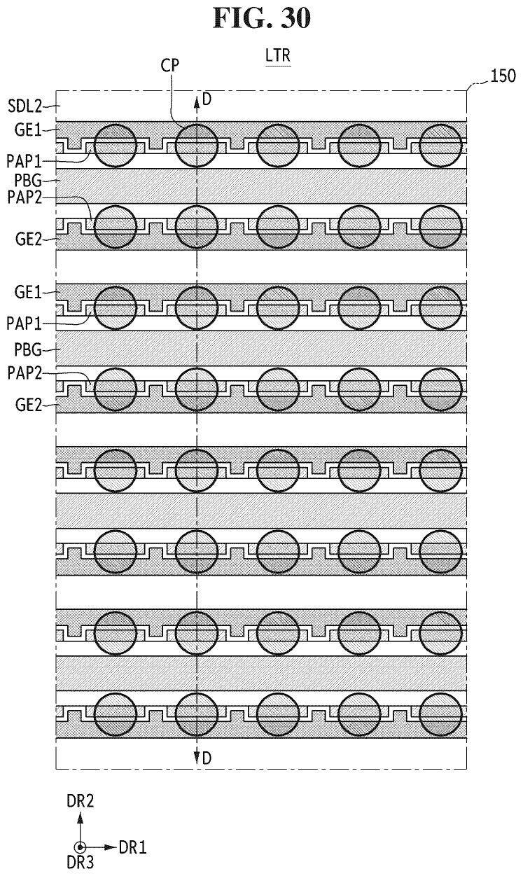

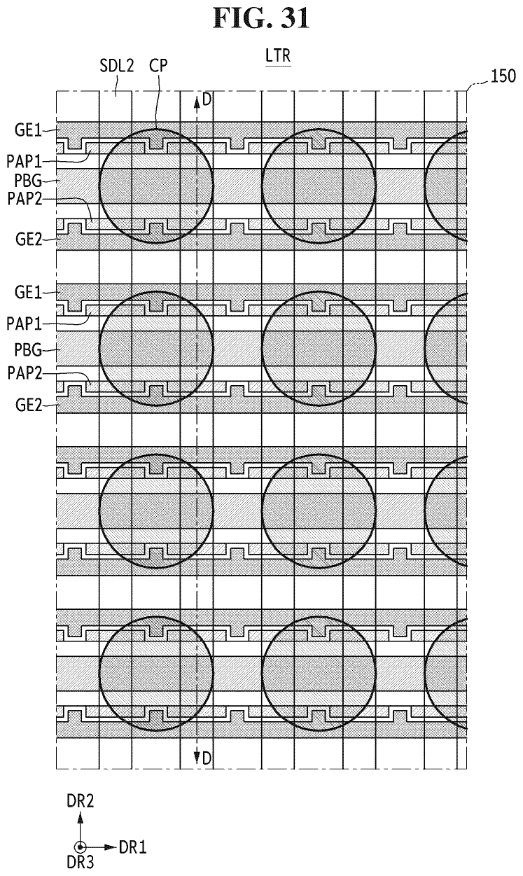

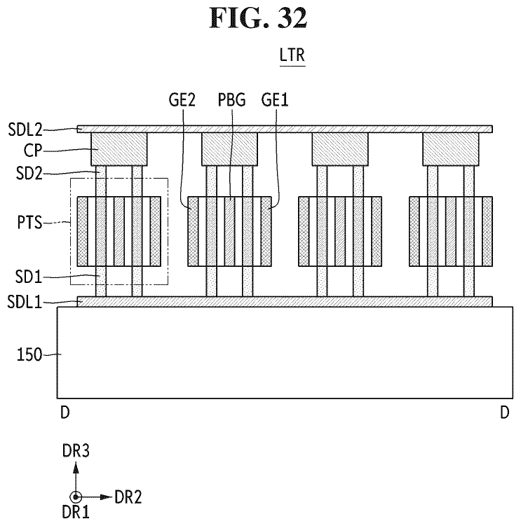

FIGS. 26, 28, 30, 31, and 33 are layout views of logic transistors of semiconductor memory devices according to some embodiments. FIG. 27 is a cross-sectional view taken along line D-D in FIGS. 26, 30, or 33. FIG. 29 is a cross-sectional view taken along line D-D in FIG. 28. FIG. 32 is a cross-sectional view taken along line D-D in FIG. 31. For convenience of explanation, the following description will primarily focus on differences from the embodiments of FIGS. 1 through 25.

Referring to FIGS. 26 through 33, in some embodiments, a logic transistor LTR may have the circuit configuration illustrated in FIG. 25. The logic transistor LTR may include peripheral transistor structures PTS that are arranged on a lower structure 150 along a first direction DR1 and a second direction DR2. In FIGS. 26 through 33, first peripheral shielding gate electrodes PSG1, second peripheral shielding gate electrodes PSG2, third peripheral shielding gate electrodes PSG3, and fourth peripheral shielding gate electrodes PSG4 are omitted. In FIGS. 26 through 33, a peripheral circuit structure PS may include first peripheral shielding gate electrodes PSG1, second peripheral shielding gate electrodes PSG2, third peripheral shielding gate electrodes PSG3, and/or fourth peripheral shielding gate electrodes PSG4. The lower structure 150 may be a semiconductor substrate, an insulating substrate, a conductive film, or an insulating film.

First source/drain connection wirings SDL1 connecting first dopant regions SD1 of peripheral transistor structures PTS may have a line shape extending along the second direction DR2 and may be spaced apart along the first direction DR1. Second source/drain connection wirings SDL2 connecting second dopant regions SD2 of the peripheral transistor structures PTS may have a line shape extending along the second direction DR2 and may be spaced apart along the first direction DR1. The second source/drain connection wirings SDL2 may be connected to conductive patterns CP.

Referring to FIGS. 26 and 27, in some embodiments, the conductive patterns CP may overlap first peripheral active patterns PAP1 and second peripheral active patterns PAP2.

The conductive patterns CP may be connected to second dopant regions SD2 of the first peripheral active patterns PAP1 and second peripheral active patterns PAP2. The conductive patterns CP may be arranged two-dimensionally along the first and second directions DR2 and may be formed as islands that are spaced apart. The second source/drain connection wirings SDL2 may connect conductive patterns CP that are spaced apart in the second direction DR2.

Referring to FIGS. 28 and 29, in some embodiments, the conductive patterns CP may have a line shape extending in the second direction DR2 and may be spaced apart along the first direction DR1.

Referring to FIGS. 27 and 30, in some embodiments, the second source/drain connection wiring SDL2 may have a plate shape. That is, the second source/drain connection wiring SDL2 in FIGS. 26 and 27 may be connected to one another.

Referring to FIGS. 31 and 32, in some embodiments, a single conductive pattern CP may overlap a plurality of adjacent first or second peripheral active patterns PAP1 or PAP2. For example, one conductive pattern CP may overlap four adjacent first or second peripheral active patterns PAP1 or PAP2.

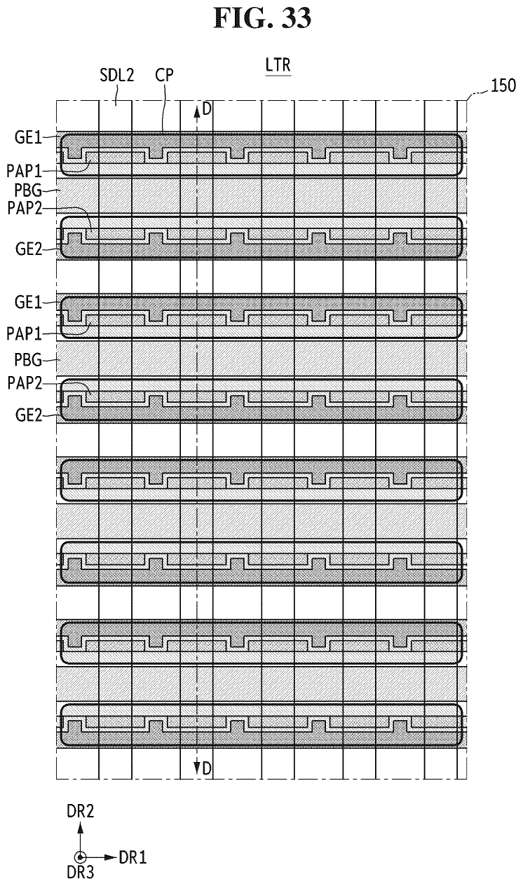

Referring to FIGS. 27 and 33, in some embodiments, the conductive patterns CP may have a line shape extending along the first direction DR1 and may be spaced apart in the second direction DR2.

The logic transistor LTR described with reference to FIGS. 25 through 33 may be positioned in the peripheral circuit area PCR of the cell structure CS described with reference to FIGS. 1 through 24 and may be included in the peripheral circuits. The first source/drain connection wirings SDL1 described with reference to FIGS. 25 through 33 may be connected to or correspond to the peripheral wirings 160P described with reference to FIGS. 1 through 24.

The second source/drain connection wirings SDL2 described with reference to FIGS. 25 through 33 may be connected to or correspond to the electrode pads EP described with reference to FIGS. 1 through 24.

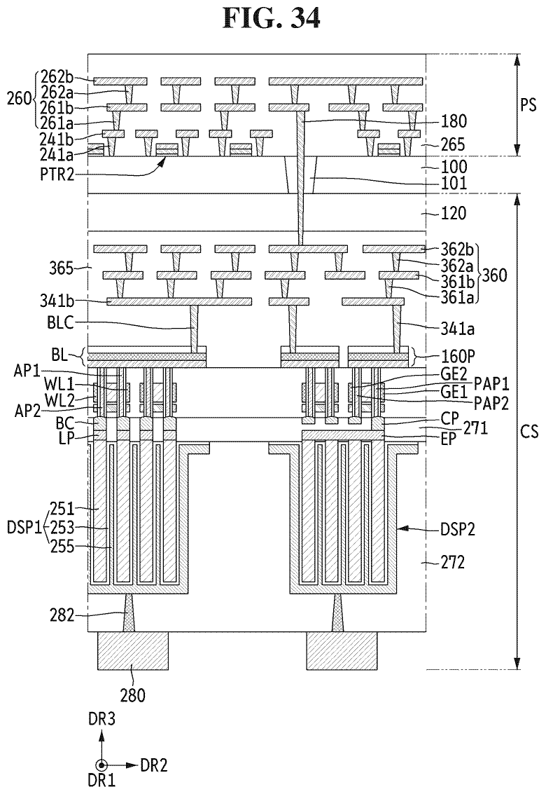

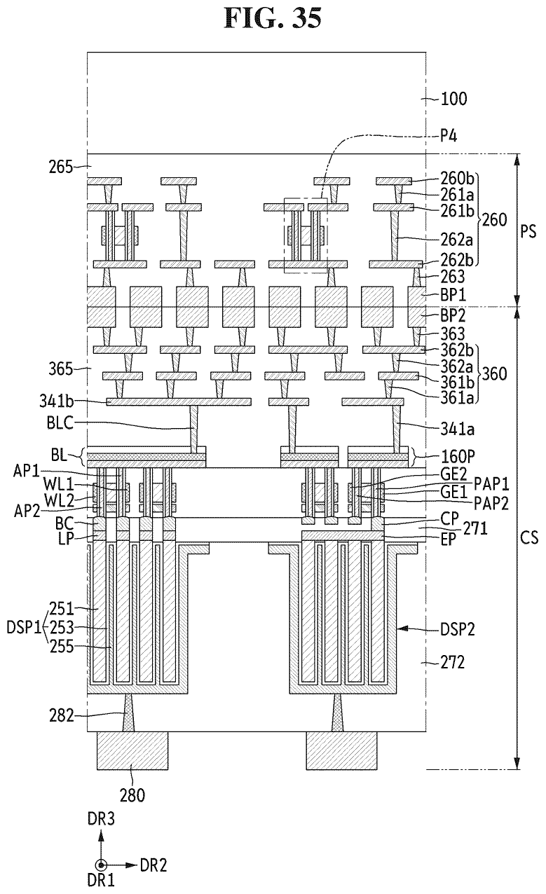

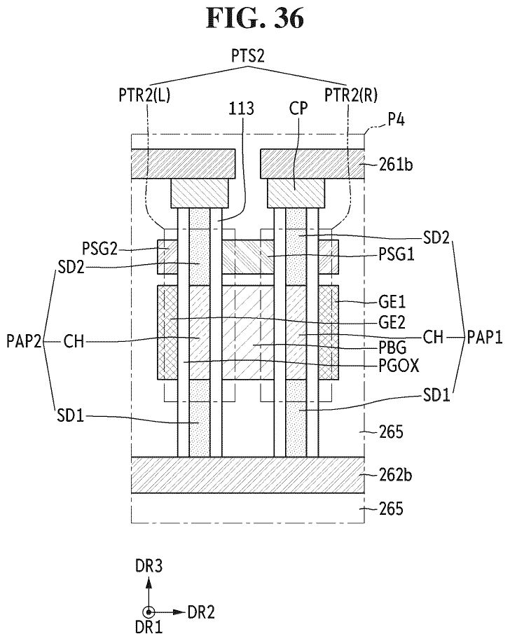

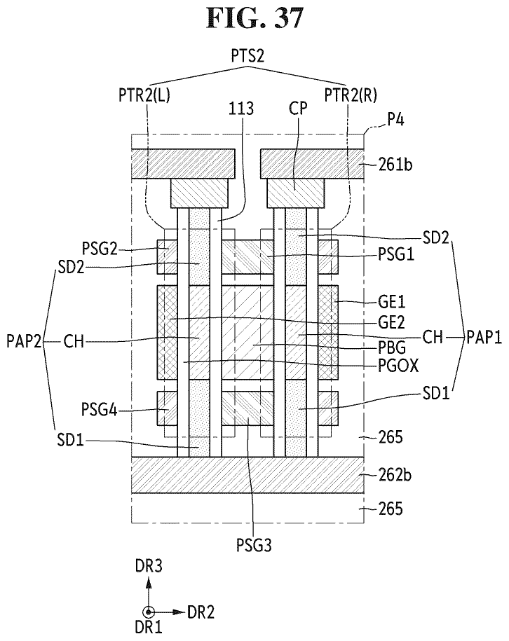

FIGS. 34 and 35 are cross-sectional views illustrating semiconductor memory devices according to some embodiments. FIGS. 36 and 37 are enlarged cross-sectional views of portion P4 in FIG. 35. For convenience of explanation, the following description will primarily focus on differences from the embodiments of FIGS. 1 through 33.

Referring to FIG. 34, in the semiconductor memory device according to some embodiments, a substrate 100 may be positioned between a cell structure CS and a peripheral circuit structure PS. The peripheral circuit structure PS may be positioned on a front surface of the substrate 100, and the cell structure CS may be positioned on a rear surface of the substrate 100.

In some embodiments, the cell structure CS and the peripheral circuit structure PS may be connected by a direct bonding method using through vias 180. The through vias 180 may extend in a third direction DR3 to connect the peripheral circuit structure PS and the cell structure CS.

For example, the cell structure CS may further include a buffer layer 120 on the rear surface of the substrate 100. The buffer layer 120 may be positioned between the substrate 100 and a cell interlayer insulating film 365. Spacers 101 may be positioned in the substrate 100. The buffer layer 120 and the spacers 101 may each include an insulating material. The through vias 180 may extend in the third direction DR3 to connect a cell connection structure 360 and a peripheral connection structure 260. For example, the through vias 180 may contact peripheral connection wirings 261b and cell connection wirings 362b. The through vias 180 may penetrate a peripheral interlayer insulating film 265, the substrate 100, the buffer layer 120, and the cell interlayer insulating film 365. The through vias 180 may include a conductive material.

Referring to FIGS. 35 and 36, in the semiconductor memory device according to some embodiments, second peripheral transistors PTR2 may be VCTs.

First peripheral active patterns PAP1 and second peripheral active patterns PAP2 and first peripheral gate electrodes GE1 and second peripheral gate electrodes GE2 may be further positioned in the peripheral interlayer insulating film 265. First dopant regions SD1 of the first peripheral active patterns PAP1 and second peripheral active patterns PAP2 in the peripheral interlayer insulating film 265 may be connected to peripheral connection wirings 262b. Second dopant regions SD2 of the first peripheral active patterns PAP1 and second peripheral active patterns PAP2 in the peripheral interlayer insulating film 265 may be connected to conductive patterns CP in the peripheral interlayer insulating film 265. The conductive patterns CP in the peripheral interlayer insulating film 265 may be connected to the peripheral connection wirings 262b.

Each of second peripheral transistor structures PTS2 may include a pair of right and left peripheral transistors PTR2(R) and PTR2(L) adjacent to one another. Each of the right peripheral transistors PTR2(R) of the second peripheral transistor structures PTS2 may include a first peripheral gate electrode GE1 and a first peripheral active pattern PAP1 adjacent to one another. First dopant regions SD1 and second dopant regions SD2 of the first peripheral active patterns PAP1 may correspond to first source/drain electrodes and second source/drain electrodes, respectively, of the right peripheral transistors PTR2(R), and channel regions CH of the first peripheral active patterns PAP1 may correspond to channel regions of the right peripheral transistors PTR2(R). Each of the left peripheral transistors PTR2(L) of the second peripheral transistor structures PTS2 may include a second peripheral gate electrode GE2 and a second peripheral active pattern PAP2 adjacent to one another. First dopant regions SD1 and second dopant regions SD2 of the second peripheral active patterns PAP2 may correspond to a first source/drain electrodes and second source/drain electrodes, respectively, of the left peripheral transistors PTR2(L) and channel regions CH of the second peripheral active patterns PAP2 may correspond to channel regions of the left peripheral transistors PTR2(L).

Referring to FIG. 36, in some embodiments, at least one of a first peripheral shielding gate electrode PSG1 overlapping a peripheral back gate electrode PBG in the third direction DR3 and a second peripheral shielding gate electrode PSG2 overlapping first and second peripheral gate electrodes GE1 and GE2 in the third direction DR3 may be further provided. The first and second peripheral shielding gate electrodes PSG1 and PSG2 may be positioned in the peripheral interlayer insulating film 265. The first and second peripheral shielding gate electrodes PSG1 and PSG2 may overlap second dopant regions SD2 of first and second peripheral active patterns PAP1 and PAP2 in a second direction DR2. Each of right and left peripheral transistors PTR2(R) and PTR2(L) of a second peripheral transistor structure PTS2 may further include at least one of the peripheral back gate electrode PBG, the first peripheral shielding gate electrode PSG1, or the second peripheral shielding gate electrode PSG2.

Referring to FIG. 37, in some embodiments, at least one of a third peripheral shielding gate electrode PSG3 overlapping the peripheral back gate electrode PBG in the third direction DR3 and a fourth peripheral shielding gate electrode PSG4 overlapping the first and second peripheral gate electrodes GE1 and GE2 in the third direction DR3 may be further provided. The third and fourth peripheral shielding gate electrodes PSG3 and PSG4 may be positioned in the peripheral interlayer insulating film 265. The third and fourth peripheral shielding gate electrodes PSG3 and PSG4 may overlap first dopant regions SD1 of the first and second peripheral active patterns PAP1 and PAP2 in the second direction DR2. Each of the right and left peripheral transistors PTR2(R) and PTR2(L) may further include at least one of the peripheral back gate electrode PBG, the third peripheral shielding gate electrode PSG3, or the fourth peripheral shielding gate electrode PSG4.

Alternatively, the second peripheral transistor structures PTS2 may have the same structure as the first peripheral transistor structures PTS1 described with reference to FIGS. 1 through 23. Alternatively, the logic transistor LTR described with reference to FIGS. 25 through 33 may be positioned in the peripheral circuit structure PS and may be included in a core circuit, a peripheral circuit, or both.

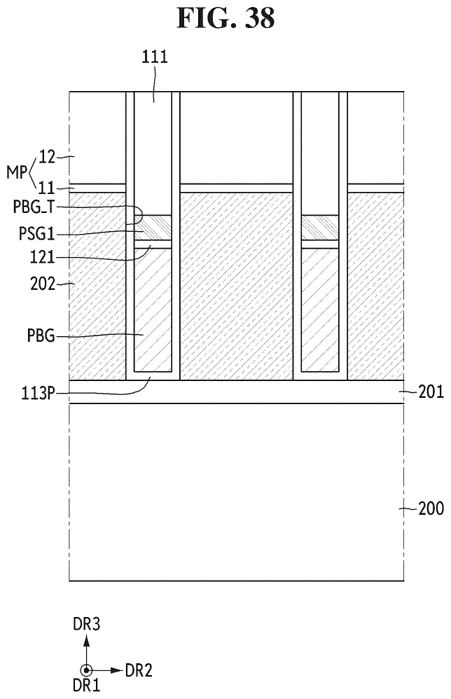

FIGS. 38 through 43 are cross-sectional views illustrating intermediate steps of a method for manufacturing a semiconductor memory device according to some embodiments.

Referring to FIG. 38, a buried insulating layer 201 and an active layer 202 may be formed on a sub-substrate 200.

For example, the sub-substrate 200, the buried insulating layer 201, and the active layer 202 may form a silicon-on-insulator (SOI) substrate. The buried insulating layer 201 may be a buried oxide (BOX) formed by a separation-by-implanted oxygen (SIMOX) method or a bonding and layer transfer method. Alternatively, the buried insulating layer 201 may be an insulating film formed by a chemical vapor deposition (CVD) method. The buried insulating layer 201 may include, for example, a silicon oxide film, a silicon nitride film, a silicon oxynitride film, and/or a low-k insulating film. The active layer 202 may be a monocrystalline semiconductor film. The active layer 202 may be, for example, a monocrystalline silicon substrate, a germanium substrate, and/or a silicon-germanium substrate.

Thereafter, a mask pattern MP may be formed on the active layer 202. The mask pattern MP may include a lower mask film 11 and an upper mask film 12 that are sequentially stacked. The upper mask film 12 may include a material having etch selectivity with respect to the lower mask film 11. For example, the lower mask film 11 may include silicon oxide, and the upper mask film 12 may include silicon nitride, although not limited thereto.

Thereafter, the active layer 202 may be anisotropically etched using the mask pattern MP as an etch mask. Accordingly, peripheral back gate trenches PBG_T may be formed in the active layer 202. The peripheral back gate trenches PBG_T may expose the buried insulating layer 201. Unlike what is illustrated, at least portions of the buried insulating layer 201 may be removed during the formation of the peripheral back gate trenches PBG_T.

Thereafter, peripheral back gate insulating patterns 113P may be formed along the bottom surfaces and sidewalls of the peripheral back gate trenches PBG_T. A peripheral back gate conductive film may then be formed on the peripheral back gate insulating patterns 113P in the peripheral back gate trenches PBG_T, and peripheral back gate electrodes PBG may be formed by etching back portions of the peripheral back gate conductive film. The peripheral back gate electrode PBG may fill a portion of the peripheral back gate trench PBG_T.

Thereafter, a first shielding isolation film may be formed on the peripheral back gate electrodes PBG in the peripheral back gate trenches PBG_T, and first shielding isolation patterns 121 may be formed by etching back portions of the first shielding isolation film. The first shielding isolation patterns 121 may fill portions of the peripheral back gate trenches PBG_T.

Thereafter, a first peripheral shielding gate conductive film may be formed on the first shielding isolation patterns 121 in the peripheral back gate trenches PBG_T, and first peripheral shielding gate electrodes PSG1 may be formed by etching back the first peripheral shielding gate conductive film. The first peripheral shielding gate electrodes PSG1 may fill portions of the peripheral back gate trenches PBG_T.

Thereafter, first shielding capping patterns 111 may be formed on the first peripheral shielding gate electrodes PSG1 to fill the peripheral back gate trenches PBG_T.

Meanwhile, according to some embodiments, before the formation of the peripheral back gate insulating patterns 113P, a gas phase doping (GPD) process or a plasma doping (PLAD) process may be performed. Through this process, impurities may be doped into portions of the active layer 202 exposed by the peripheral back gate trenches PBG_T.

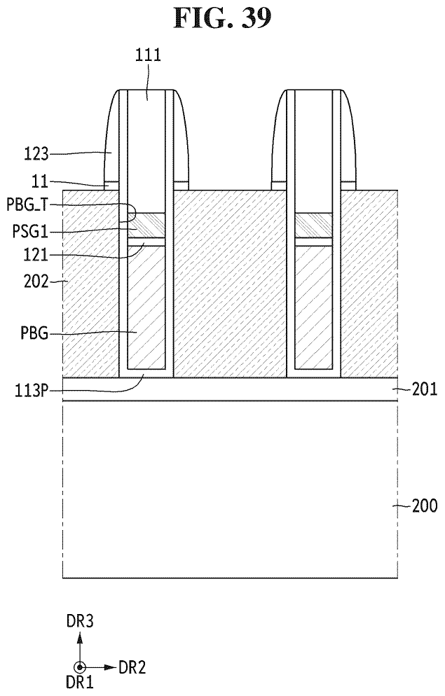

Referring to FIGS. 38 and 39, portions of the mask pattern MP may be removed, thereby forming a pair of spacer patterns 123 on either side of each of the first shielding capping patterns 111 in the peripheral back gate trenches PBG_T.

Specifically, the upper mask film 12 of the mask pattern MP may be removed, thereby exposing the lower mask film 11. As a result, the first shielding capping patterns 111 may protrude in a third direction DR3 from the top surface of the lower mask film 11.

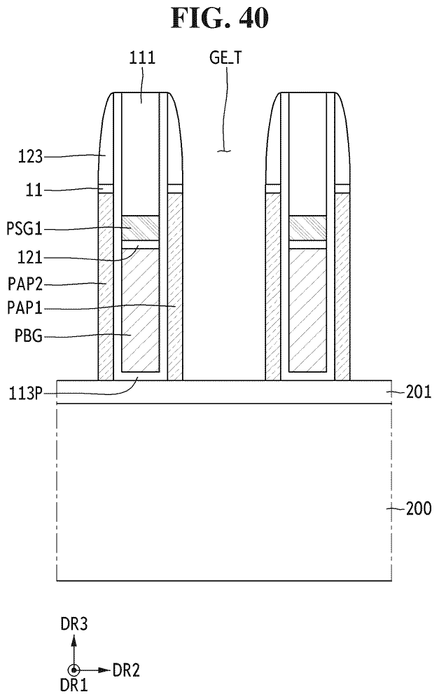

Thereafter, a spacer film may be formed on the top surface of the lower mask film 11, the sidewalls of the peripheral back gate insulating patterns 113P, and the top surfaces of the first shielding capping patterns 111, and may then be patterned, thereby forming the spacer patterns 123. The width of first peripheral active patterns PAP1 (in FIG. 40) and second peripheral active patterns PAP2 (in FIG. 40) may be determined based on the deposition thickness of the spacer film. The spacer patterns 123 may include an insulating material.

Referring to FIGS. 39 and 40, an anisotropic etching process may be performed on the active layer 202 using the spacer patterns 123 as an etch mask. Through this, a pair of separated first and second peripheral active patterns PAP1 and PAP2 may be formed on either side of each of the peripheral back gate insulating patterns 113P. As a result of the formation of the first peripheral active patterns PAP1 and the second peripheral active patterns PAP2, the buried insulating layer 201 may be exposed.

The first peripheral active patterns PAP1 and the second peripheral active patterns PAP2 adjacent thereto may define peripheral gate electrode trenches GE_T. The peripheral gate electrode trenches GE_T may be formed between the first peripheral active patterns PAP1 and the second peripheral active patterns PAP2.

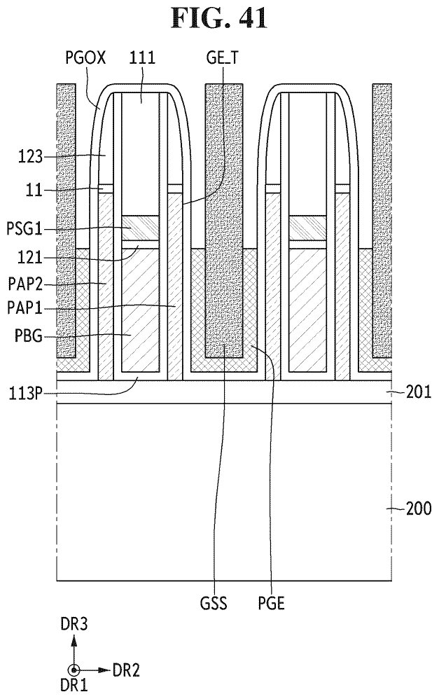

Referring to FIGS. 40 and 41, peripheral gate insulating patterns PGOX may be formed along the bottom surfaces and sidewalls of the peripheral gate electrode trenches GE_T. The peripheral gate insulating patterns PGOX may be formed along the sidewalls of the first peripheral active patterns PAP1 and second peripheral active patterns PAP2, the top surfaces of the peripheral back gate insulating patterns 113P, the top surfaces of the first shielding capping patterns 111, the top surfaces of the spacer patterns 123, and the top surface of the buried insulating layer 201. The peripheral gate insulating patterns PGOX may be formed using at least one of physical vapor deposition (PVD), thermal chemical vapor deposition (thermal CVD), low-pressure chemical vapor deposition (LP-CVD), plasma-enhanced chemical vapor deposition (PE-CVD), or atomic layer deposition (ALD), although not limited thereto.

A peripheral gate conductive film PGE may be formed along the peripheral gate insulating patterns PGOX. The peripheral gate conductive film PGE may be conformally formed along the surfaces of the peripheral gate electrode trenches GE_T.

Thereafter, gate separation patterns GSS that cover the peripheral gate conductive film PGE and fill the peripheral gate electrode trenches GE_T may be formed. Portions of the gate separation patterns GSS may be removed, thereby exposing portions of the peripheral gate conductive film PGE and the peripheral gate insulating patterns PGOX. Then, the exposed portions of the peripheral gate conductive film PGE may be etched back so that the peripheral gate conductive film PGE has a U-shaped cross-section.

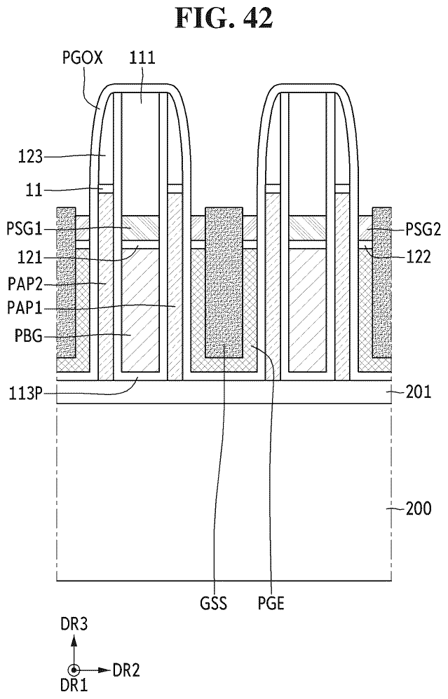

Referring to FIGS. 41 and 42, a second shielding isolation film may be formed on the peripheral gate conductive film PGE, and second shielding isolation patterns 122 may be formed by etching back portions of the second shielding isolation film. For example, during the etching back process, portions of the gate separation patterns GSS may also be removed, although not limited thereto.

Thereafter, a second peripheral shielding gate conductive film may be formed on the second shielding isolation patterns 122, and second peripheral shielding gate electrodes PSG2 may be formed by etching back the second peripheral shielding gate conductive film.

In some embodiments, either the formation of the first shielding isolation patterns 121 and the first peripheral shielding gate electrodes PSG1 or the formation of the second shielding isolation patterns 122 and the second peripheral shielding gate electrodes PSG2 may be omitted.

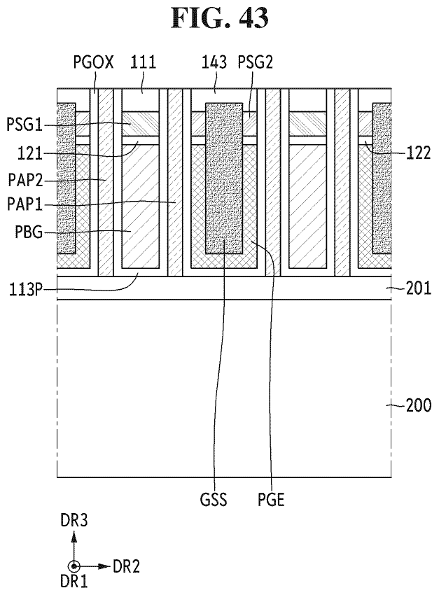

Referring to FIGS. 42 and 43, second shielding capping patterns 143 covering the second peripheral shielding gate electrodes PSG2 and the gate separation patterns GSS may be formed. The second shielding capping patterns 143 may fill the remaining portions of the peripheral gate electrode trenches GE_T of FIG. 40, in which the peripheral gate conductive film PGE, the second shielding isolation patterns 122, and the second peripheral shielding gate electrodes PSG2 are formed.

During the formation of the second shielding capping patterns 143, portions of the peripheral gate insulating patterns PGOX, portions of the first shielding capping patterns 111, the spacer patterns 123, and the lower mask film 11 may be removed. Through this, the first peripheral active patterns PAP1 and the second peripheral active patterns PAP2 may be exposed. At this time, portion of the first peripheral active patterns PAP1 and second peripheral active patterns PAP2 may also be etched.

Thereafter, referring to FIGS. 43 and 5, a first interlayer insulating film 271, conductive patterns CP, and electrode pads EP may be formed. The conductive patterns CP may be formed on the first peripheral active patterns PAP1 and the second peripheral active patterns PAP2. The electrode pads EP may be connected to the conductive patterns CP. Peripheral capacitors DSP2 may be formed on the conductive patterns CP. A second interlayer insulating film 272 may be formed on the peripheral capacitors DSP2.

Thereafter, a back grinding (lapping) process for removing the sub-substrate 200 may be performed. The removal of the sub-substrate 200 may include exposing the buried insulating layer 201 by sequentially performing a grinding process and a wet etching process.

Thereafter, the buried insulating layer 201 may be removed, thereby exposing the first peripheral active patterns PAP1, the second peripheral active patterns PAP2, the peripheral gate insulating patterns PGOX, and the peripheral back gate insulating patterns 113P.

Thereafter, the exposed peripheral gate insulating pattern PGOX and peripheral back gate insulating pattern 113P may be removed to expose the peripheral back gate electrode PBG and the peripheral gate conductive film PGE.

Thereafter, portions of the peripheral back gate electrodes PBG may be removed, and back gate capping patterns 115 may be formed on the peripheral back gate electrodes PBG. In addition, portions of the peripheral gate conductive film PGE may be removed, thereby forming pairs of first peripheral gate electrodes GE1 and second peripheral gate electrodes GE2. Gate capping patterns 145 may be formed on the first peripheral gate electrodes GE1 and the second peripheral gate electrodes GE2.

First cell active patterns AP1, second cell active patterns AP2, cell back gate electrodes BG, first cell shielding gate electrodes SG1, second cell shielding gate electrodes SG 2, cell back gate insulating patterns 113, cell gate insulating patterns GOX, contact patterns BC, landing pads LP, and cell capacitors DSP1 may be formed simultaneously with the first peripheral active patterns PAP1, the second peripheral active patterns PAP2, the peripheral back gate electrodes PBG, the first peripheral shielding gate electrodes PSG1, the second peripheral shielding gate electrodes PSG2, the peripheral back gate insulating patterns 113P, the peripheral gate insulating patterns PGOX, the conductive patterns CP, the electrode pads EP, and the peripheral capacitors DSP2.

Thereafter, bitlines BL, peripheral wirings 160P, bitline contacts BLC, peripheral contacts 341a, cell wiring lines 341b, a cell connection structure 360, cell bonding pad plugs 363, cell bonding pads BP2, and a cell interlayer insulating film 365 may be formed.

Thereafter, peripheral bonding pads BP1 of a peripheral circuit structure PS formed on the substrate 100 may be bonded to the cell bonding pad BP2, and a peripheral interlayer insulating film 265 of the peripheral circuit structure PS formed on a substrate 100 may be bonded to the cell interlayer insulating film 365. Then, connection pad plugs 282 and connection pads 280 may be formed.

Although the embodiments of the present disclosure have been described above with reference to the accompanying drawings, the present disclosure is not limited to the above-described embodiments and may be embodied in various other forms. Those skilled in the art to which the present disclosure pertains will understand that the technical spirit or essential features of the present disclosure can be implemented in other specific forms without changing them.

Therefore, it should be understood that the above-described embodiments are illustrative in all respects and not restrictive.

What is claimed is:

1. A semiconductor memory device comprising:
a substrate including a cell array area and a peripheral circuit area;
a cell active pattern extending in a first direction in the cell array area of the substrate;
a wordline and a first cell shielding gate electrode spaced apart in the first direction on the cell active pattern;
a plurality of first peripheral gate electrodes spaced apart in a second direction on the peripheral circuit area of the substrate;
a plurality of first peripheral active patterns and a plurality of second peripheral active pattern, both extending in the first direction and adjacent to one another in the second direction, the plurality of first peripheral active patterns and the plurality of second peripheral active patterns respectively between adjacent ones of the plurality of first peripheral gate electrodes in the second direction; and
a plurality of first peripheral shielding gate electrodes respectively spaced apart in the first direction from the plurality of first peripheral gate electrodes.

2. The semiconductor memory device of claim 1, further comprising:
a plurality of second peripheral gate electrodes respectively between the plurality of first peripheral active patterns and the plurality of second peripheral active patterns.

3. The semiconductor memory device of claim 2, wherein a same voltage is applied to the plurality of first peripheral gate electrodes and the plurality of second peripheral gate electrodes.

4. The semiconductor memory device of claim 2, wherein different voltages are applied to the plurality of first peripheral gate electrodes and the plurality of second peripheral gate electrodes.

5. The semiconductor memory device of claim 2, wherein each of the plurality of first peripheral active patterns and the plurality of second peripheral active patterns includes a dopant region doped with a dopant of a first conductivity type.

6. The semiconductor memory device of claim 2, wherein:
each of the plurality of first peripheral active patterns includes a first dopant region doped with a dopant of a first conductivity type, and
each of the plurality of second peripheral active patterns includes a second dopant region doped with a dopant of a second conductivity type different from the first conductivity type.

7. The semiconductor memory device of claim 2, further comprising:
a plurality of second peripheral shielding gate electrodes respectively spaced apart in the first direction from the plurality of second peripheral gate electrodes, between the plurality of first peripheral active patterns and the plurality of second peripheral active patterns.

8. The semiconductor memory device of claim 1, further comprising:
a plurality of second peripheral shielding gate electrodes respectively spaced apart in the first direction from the plurality of first peripheral gate electrodes,
wherein each of the plurality of first peripheral gate electrodes is between the plurality of first peripheral shielding gate electrodes and the plurality of second peripheral shielding gate electrodes.

9. The semiconductor memory device of claim 7, wherein:
the plurality of first peripheral gate electrodes include first sub-gate electrodes adjacent to each other in the first direction,
the plurality of second peripheral gate electrodes include second sub-gate electrodes adjacent to each other in the first direction,
a first peripheral active pattern among the plurality of first peripheral active patterns that is disposed between the first sub-gate electrodes and a second peripheral active pattern among the plurality of second peripheral active patterns that is disposed between the first sub-gate electrodes include first dopant regions doped with a dopant of a first conductivity type,
a first peripheral active pattern among the plurality of second peripheral active patterns that is disposed between the second sub-gate electrodes and a second peripheral active pattern among the plurality of second peripheral active patterns that is disposed the second sub-gate electrodes include second dopant regions doped with a dopant of a second conductivity type different from the first conductivity type, and
different voltages are applied to the plurality of first peripheral shielding gate electrodes on the first sub-gate electrodes and the plurality of second peripheral shielding gate electrodes on the second sub-gate electrodes.

10. A semiconductor memory device comprising:
a substrate including a cell array area and a peripheral circuit area;
a plurality of first peripheral gate electrodes extending in a first direction and arranged in a second direction, on the peripheral circuit area of the substrate;
a plurality of second peripheral gate electrodes extending in the first direction respectively between the plurality of first peripheral gate electrodes;
a plurality of peripheral active patterns extending in a third direction and including first dopant regions and second dopant regions, between each of the plurality of first peripheral gate electrodes and each of the plurality of the second peripheral gate electrodes;
a plurality of first peripheral shielding gate electrodes spaced apart in the third direction from the plurality of first peripheral gate electrodes;
a plurality of second peripheral shielding gate electrodes spaced apart in the third direction from the plurality of second peripheral gate electrodes; and
a plurality of conductive patterns on the second dopant regions of the plurality of peripheral active patterns,
wherein the plurality of first peripheral shielding gate electrodes and the plurality of second peripheral shielding gate electrodes overlap the second dopant regions of the plurality of peripheral active patterns in the second direction.

11. The semiconductor memory device of claim 10, further comprising:
a first source/drain line connected to the first dopant regions of the plurality of peripheral active patterns; and
a second source/drain line connected to the plurality of conductive patterns and the second dopant regions of plurality of the peripheral active patterns.

12. The semiconductor memory device of claim 10, wherein each of the plurality of conductive patterns is connected to the second dopant region of a corresponding peripheral active pattern.

13. The semiconductor memory device of claim 10, wherein each of the plurality of conductive patterns is connected to the second dopant regions of adjacent peripheral active patterns among plurality of the peripheral active patterns.

14. The semiconductor memory device of claim 10, wherein each of the plurality of conductive patterns extends in the first direction and is connected to the second dopant regions of the plurality of peripheral active patterns that are spaced apart in the first direction.

15. The semiconductor memory device of claim 10, wherein each of the plurality of conductive patterns extends in the second direction and is connected to the second dopant regions of the plurality of peripheral active patterns that are spaced apart in the second direction.

16. A semiconductor memory device comprising:
a substrate including a cell array area and a peripheral circuit area; and
a cell structure and a peripheral circuit structure on the substrate, the cell structure and the peripheral circuit structure overlapping in a first direction and being electrically connected,
wherein
the cell structure includes a plurality of memory cells on the cell array area of the substrate and a plurality of first peripheral transistors on the peripheral circuit area of the substrate,
the peripheral circuit structure includes a plurality of second peripheral transistors,
the plurality of memory cells include a plurality of cell transistors and a plurality of cell capacitors, and
the plurality of first peripheral transistors include a first peripheral active pattern extending in the first direction, and a first peripheral gate electrode and a first peripheral shielding gate electrode spaced apart in the first direction on the first peripheral active pattern.

17. The semiconductor memory device of claim 16, wherein the second peripheral transistors include a second peripheral active pattern extending in the first direction and a second peripheral gate electrode on the second peripheral active pattern.

18. The semiconductor memory device of claim 17, wherein
the plurality of second peripheral transistors further include a second peripheral shielding gate electrode spaced apart in the first direction from the second peripheral gate electrode, on the second peripheral active pattern.

19. The semiconductor memory device of claim 16, wherein
the cell structure further includes a cell bonding pad,
the peripheral circuit structure further includes a peripheral bonding pad, and
the cell bonding pad are in contact with the peripheral bonding pad.

20. The semiconductor memory device of claim 16, wherein
the cell structure further includes a cell connection structure connected to the plurality of memory cells and the plurality of first peripheral transistors,
the peripheral circuit structure further includes a peripheral connection structure connected to the plurality of second peripheral transistors, and
the semiconductor memory device further comprises a through via that contact the cell connection structure and the peripheral connection structure.
